(19) United States
(12) Patent Application Publication
(10) Pub. No.: US 2024/0310406 A1
(43) Pub. Date: Sep. 19, 2024

(54) SENSOR AND ELECTRONIC DEVICE

(71) Applicant: KABUSHIKI KAISHA TOSHIBA, Tokyo (JP)

(72) Inventors: Kei MASUNISHI, Kawasaki Kanagawa (JP); Etsuji OGAWA, Kawasaki Kanagawa (JP); Yasushi TOMIZAWA, Fuchu Tokyo (JP)

(73) Assignee: KABUSHIKI KAISHA TOSHIBA, Tokyo (JP)

(21) Appl. No.: 18/450,747

(22) Filed: Aug. 16, 2023

(30) Foreign Application Priority Data
Mar. 13, 2023 (JP) 2023-038514

(51) Int. Cl. G01P 15/097; G01P 15/125

(52) U.S. Cl. CPC G01P 15/097; G01P 15/125; G01P 2015/0817

(57) ABSTRACT

According to one embodiment, a sensor includes an element section. The element section includes a first beam, a first beam electrode, a second beam, and a second beam electrode. The first beam includes a first portion, a first other portion, and a first intermediate portion between the first portion and the first other portion. The first beam electrode is connected to the first intermediate portion. The second beam includes a second portion, a second other portion, and a second intermediate portion between the second portion and the second other portion. The second beam electrode is connected to the second intermediate portion. The first and the second beam electrodes satisfy at least one of first to eighth conditions.

### CROSS-REFERENCE TO RELATED APPLICATIONS

This application is based upon and claims the benefit of priority from Japanese Patent Application No. 2023-038514, filed on Mar. 13, 2023; the entire contents of which are incorporated herein by reference.

### FIELD

Embodiments described herein relate generally to a sensor and an electronic device.

### BACKGROUND

For example, there is a sensor using a MEMS structure. It is desired to improve the characteristics of the sensor.

### BRIEF DESCRIPTION OF THE DRAWINGS

FIG. 1 is a schematic plan view illustrating a sensor according to a first embodiment;

FIGS. 2A to 2C are schematic cross-sectional views illustrating the sensor according to the first embodiment;

FIGS. 3A to 3D are schematic cross-sectional views illustrating the sensor according to the first embodiment;

FIG. 4 is a schematic plan view illustrating the sensor according to the first embodiment;

FIGS. 5A to 5D are schematic cross-sectional views illustrating a sensor according to the first embodiment;

FIGS. 6A to 6D are schematic cross-sectional views illustrating a sensor according to the first embodiment;

FIGS. 7A to 7D are schematic cross-sectional views illustrating a sensor according to the first embodiment;

FIGS. 8A to 8D are schematic cross-sectional views illustrating a sensor according to the first embodiment;

FIGS. 9A to 9D are schematic cross-sectional views illustrating a sensor according to the first embodiment;

FIGS. 10A to 10D are schematic cross-sectional views illustrating the sensor according to the first embodiment;

FIGS. 11A and 11B are schematic plan views illustrating a part of a sensor according to the first embodiment;

FIG. 12 is a schematic plan view illustrating a sensor according to the first embodiment;

FIGS. 13A and 13B are schematic plan views illustrating the sensor according to the first embodiment;

FIG. 14 is a schematic plan view illustrating a sensor according to the first embodiment;

FIG. 15 is a schematic plan view illustrating a sensor according to the first embodiment;

FIG. 16 is a schematic plan view illustrating the sensor according to the first embodiment;

FIG. 17 is a schematic plan view illustrating a sensor according to the first embodiment;

FIG. 18 is a schematic plan view illustrating a sensor according to the first embodiment;

FIG. 19 is a schematic plan view illustrating a sensor according to the first embodiment;

FIG. 20 is a schematic plan view illustrating a sensor according to the first embodiment;

FIG. 21 is a schematic plan view illustrating a sensor according to the first embodiment;

FIG. 22 is a schematic plan view illustrating a sensor according to the first embodiment;

FIG. 23 is a schematic plan view illustrating a sensor according to the first embodiment;

FIG. 24 is a schematic plan view illustrating a sensor according to the first embodiment;

FIG. 25 is a schematic plan view illustrating a sensor according to the first embodiment;

FIG. 26 is a schematic plan view illustrating a sensor according to the first embodiment;

FIG. 27 is a schematic plan view illustrating a sensor according to the first embodiment;

FIG. 28 is a schematic diagram illustrating an electronic device according to a second embodiment;

FIGS. 29A to 29H are schematic diagrams illustrating applications of the electronic device according to the embodiment; and

FIGS. 30A and 30B are schematic diagrams illustrating applications of the sensor according to the embodiment.

### DETAILED DESCRIPTION

According to one embodiment, a sensor includes an element section. The element section includes a first beam, a first beam electrode, a second beam, and a second beam electrode. The first beam includes a first portion, a first other portion, and a first intermediate portion between the first portion and the first other portion. A direction from the first portion to the first other portion is along a first direction. The first beam electrode is connected to the first intermediate portion. The second beam includes a second portion, a second other portion, and a second intermediate portion between the second portion and the second other portion. A direction from the second portion to the second other portion is along the first direction. The second beam electrode is connected to the second intermediate portion. A second direction from the first intermediate portion to the first beam electrode crosses the first direction. A direction from the second intermediate portion to the second beam electrode is along the second direction. The first beam electrode and the second beam electrode satisfy at least one of a first condition, a second condition, a third condition, a fourth condition, a fifth condition, a sixth condition, a seventh condition or an eighth condition. In the first condition, a second mass of the second beam electrode is different from a first mass of the first beam electrode. In the second condition, at least a part of a second material included in the second beam electrode is different from at least a part of a first material included in the first beam electrode. In the third condition, a second thickness of the second beam electrode along a third direction is different from a first thickness of the first beam electrode along the third direction. The third direction crosses a plane including the first direction and the second direction. In the fourth condition, a second size of the second hole included in a second beam electrode is different from a first size of a first hole included in the first beam electrode. In the fifth condition, a second density of the second holes is different from the first density of the first holes. In the sixth condition, a second number of the second holes is different from a first number of the first holes. Or the second beam electrode includes the second holes and the first beam electrode does not include the first hole. In the seventh condition, a second layer structure of the second beam electrode is different from a first layer structure of the first beam electrode. In the eighth condition, a second shape of the second beam electrode is different from a first shape of the first beam electrode.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

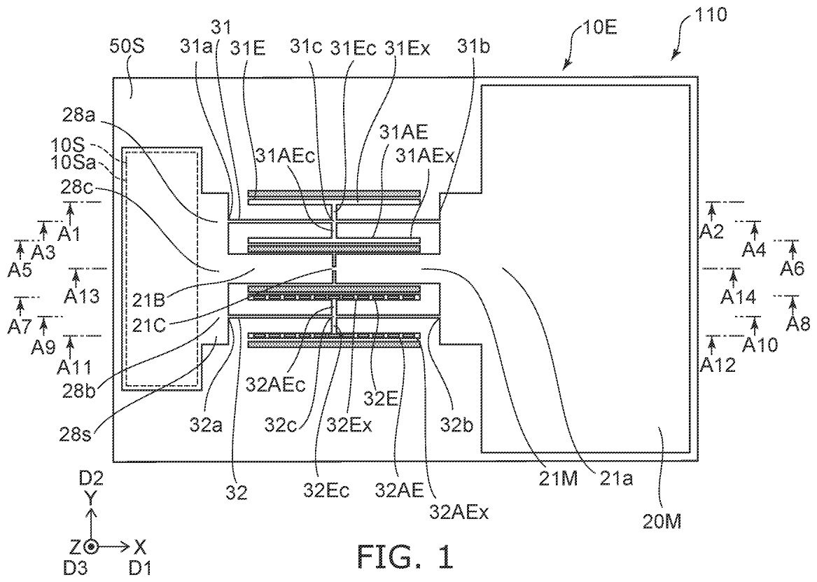

FIG. 1 is a schematic plan view illustrating a sensor according to the first embodiment.

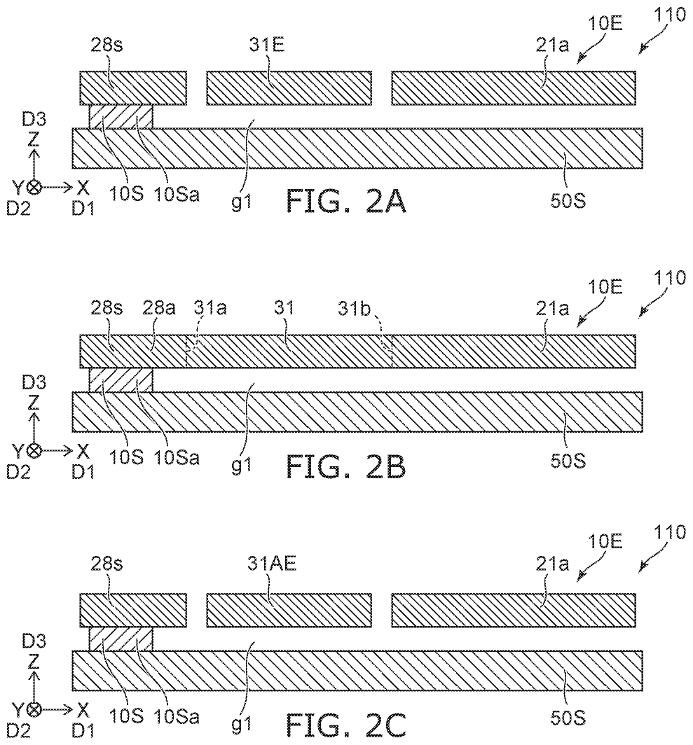

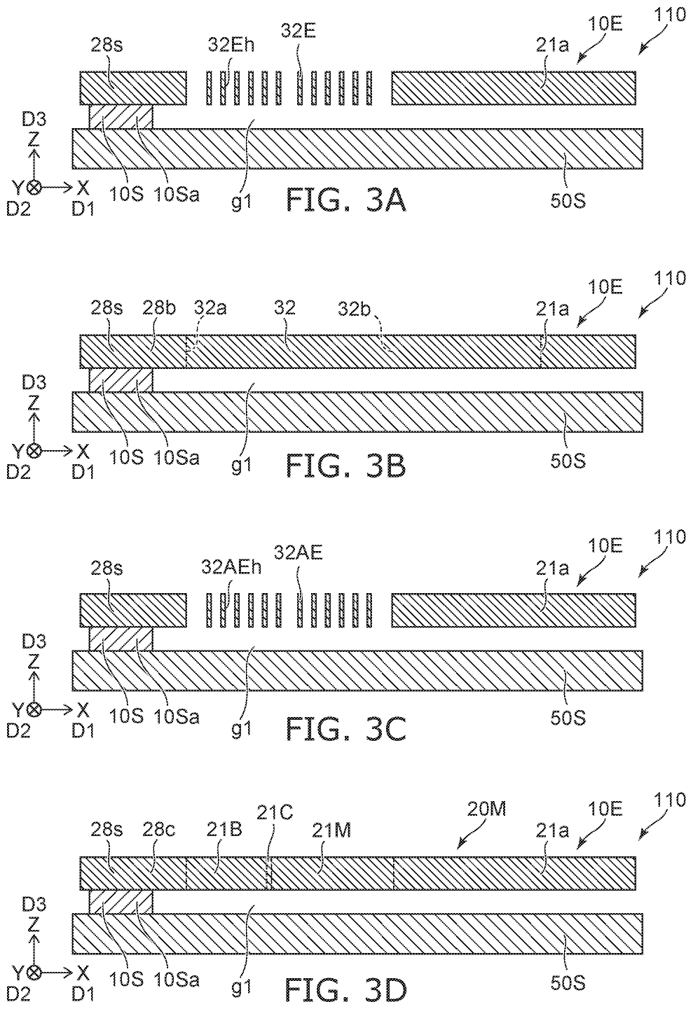

FIGS. 2A to 2C and 3A to 3D are schematic cross-sectional views illustrating the sensor according to the first embodiment.

FIGS. 2A to 2C and 3A to 3D are cross-sectional views along the line A1-A2, the line A3-A4, the line A5-A6, the line A7-A8, the line A9-A10, the line A11-A12, and the line A13-A14.

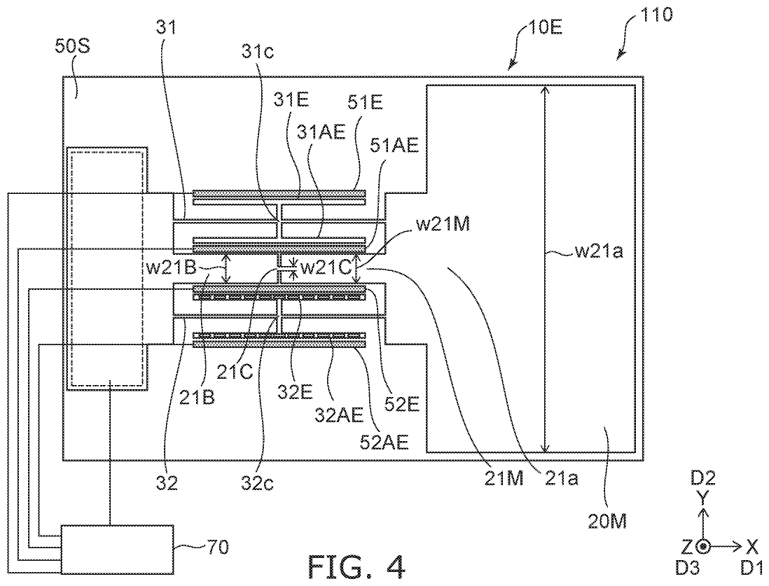

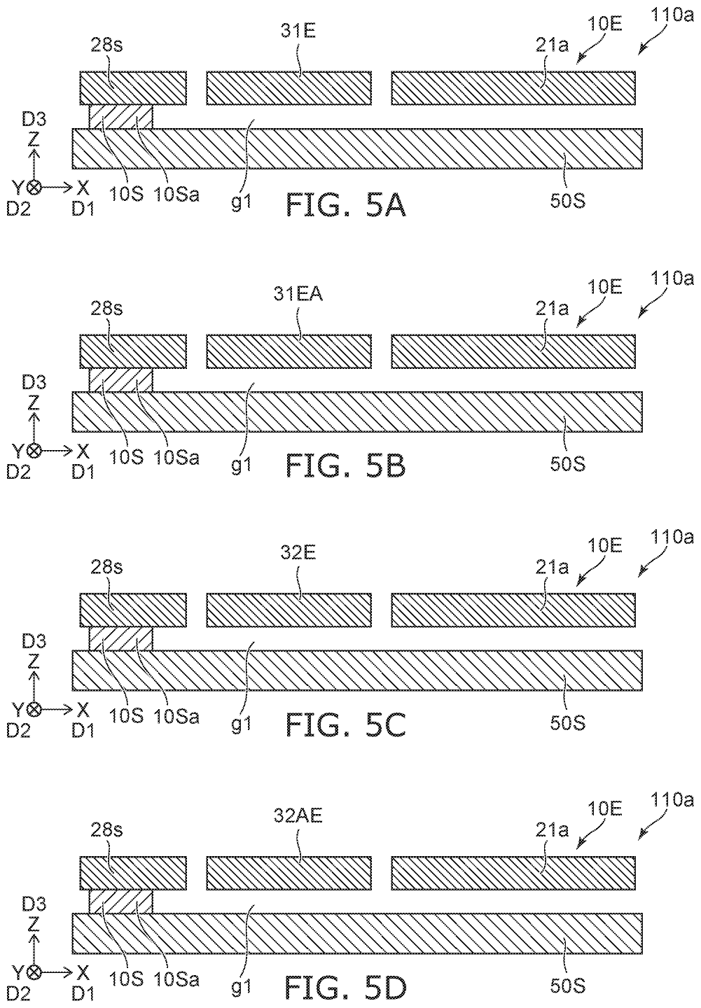

FIG. 4 is a schematic plan view illustrating the sensor according to the first embodiment.

As shown in FIG. 1, a sensor 110 according to the embodiment includes an element section 10E.

The element section 10E includes a first beam 31, a second beam 32, a first beam electrode 31E and a second beam electrode 32E.

The first beam 31 includes a first portion 31a, a first other portion 31b, and a first intermediate portion 31c. The first intermediate portion 31c is provided between the first portion 31a and the first other portion 31b. A direction from the first portion 31a to the first other portion 31b is along the first direction D1.

The first direction D1 is defined as an X-axis direction. One direction perpendicular to the X-axis direction is defined as a Y-axis direction. A direction perpendicular to the X-axis direction and the Y-axis direction is defined as a Z-axis direction.

The first beam electrode 31E is connected to the first intermediate portion 31c. A second direction D2 from the first intermediate portion 31c to the first beam electrode 31E crosses the first direction D1. The second direction D2 is, for example, the Y-axis direction.

The second beam 32 includes a second portion 32a, a second other portion 32b, and a second intermediate portion 32c. The second intermediate portion 32c is provided between the second portion 32a and the second other portion 32b. A direction from the second portion 32a to the second other portion 32b is along the first direction D1.

The second beam electrode 32E is connected to the second intermediate portion 32c. A direction from the second intermediate portion 32c to the second beam electrode 32E is along the second direction D2. In this example, a direction from the second beam 32 to the first beam 31 is along the second direction D2.

As shown in FIG. 1, in this example, the first beam electrode 31E includes a first extending portion 31Ex and a first extending connecting portion 31Ec. The first extending portion 31Ex extends along the first direction D1. The first extending connecting portion 31Ec connects the first extending portion 31Ex to the first intermediate portion 31c. The first extending connecting portion 31Ec extends, for example, along the second direction D2.

In this example, the second beam electrode 32E includes a second extending portion 32Ex and a second extending connecting portion 32Ec. The second extending portion 32Ex extends along the first direction D1. The second extending connecting portion 32Ec connects the second extending portion 32Ex to the second intermediate portion 32c. The second extending connecting portion 32Ec extends, for example, along the second direction D2.

As shown in FIGS. 2A to 2C and FIGS. 3A to 3D, the sensor 110 further includes a base 50S and a first fixed portion 10S. The first fixed portion 10S is fixed to the base 50S. A direction from the base 50S to the first fixed portion 10S is along a third direction D3. The third direction D3 crosses a plane including the first direction D1 and the second direction D2. The third direction D3 is, for example, the Z-axis direction.

The element section 10E further includes a first support portion 28S supported by the first fixed portion 10S. In this example, the first fixed portion 10S includes a first fixed region 10a. The first support portion 28S includes a first support region 28a and a second support region 28b. These support regions are supported on the first fixed region 10a.

The first portion 31a and the second portion 32a are connected to the first support portion 28S. In this example, the first portion 31a is supported by the first support region 28a. The second portion 32a is connected to the second support region 28b. A first gap g1 is provided between the base 50S and the element section 10E.

As shown in FIG. 3A, in this example, the second beam electrode 32E includes a second hole 32Eh. On the other hand, as shown in FIG. 2A, the first beam electrodes 31E are not provided with holes. In the embodiment, the configuration of the second beam electrodes 32E is different from the configuration of the first beam electrodes 31E. Thereby, the resonance characteristic of the second beam 32 differs from the resonance characteristic of the first beam 31. The resonance frequency of the second beam 32 is different from the resonance frequency of the first beam 31.

In the embodiment, the force (e.g., acceleration) applied to the element section 10E can be detected by detecting change in the resonance characteristics (e.g., resonance frequency) of the beam. In the embodiment, multiple beams with different resonance characteristics (resonance frequencies) are provided. Thereby, for example, a wide dynamic range can be provided. For example, it is possible to detect a wide dynamic range with high accuracy. According to the embodiment, it is possible to provide a sensor whose characteristics can be improved.

As shown in FIG. 4, the sensor 110 may further include a first fixed electrode 51E and a second fixed electrode 52E. The first fixed electrode 51E and the second fixed electrode 52E are fixed to the base 50S. The first fixed electrode 51E faces the first beam electrode 31E. The second fixed electrode 52E faces the second beam electrode 32E. For example, a direction from the first beam electrode 31E to the first fixed electrode 51E is along the second direction D2. For example, a direction from the second beam electrode 32E to the second fixed electrode 52E is along the second direction D2. At least a part of the first fixed electrode 51E and at least a part of the second fixed electrode 52E extend along the first direction D1.

As shown in FIG. 3, a controller 70 may be provided. The controller 70 may be included in the sensor 110. The controller 70 may be provided separately from the sensor 110. In one example, the controller 70 is configured to apply a first AC signal between the first fixed electrode 51E and the first beam electrode 31E. The controller 70 is configured to, for example, apply the first AC signal between the second fixed electrode 52E and the second beam electrode 32E. A first AC signal causes these beams to vibrate. By detecting the vibration characteristics, the received force (acceleration) can be detected.

The detecting the vibration characteristics may be performed optically. When vibrational properties are detected optically, these beams are illuminated with light and properties of the reflected light are detected. The detection of the vibration characteristics may be performed electrically, for example. If the detection of the vibration characterization is performed electrically, for example, changes in capacitance with the vibration of the beam are detected.

As shown in FIG. 4, for example, the element section 10E may further include a first opposing beam electrode 31AE and a second opposing beam electrode 32AE. The first opposing beam electrode 31AE is connected to the first intermediate portion 31c. The second opposing beam electrode 32AE is connected to the second intermediate portion 32c. The first beam 31 is provided between the first opposing beam electrode 31AE and the first beam electrode 31E in the second direction D2. The second beam 32 is provided between the second opposing beam electrode 32AE and the second beam electrode 32E in the second direction D2.

As shown in FIG. 4, for example, the sensor 110 may further include a first opposing fixed electrode 51AE and a second opposing fixed electrode 52AE fixed to the base 50S. The controller 70 is configured to detect a first signal generated between the first opposing fixed electrode 51AE and the first opposing beam electrode 31AE. The controller 70 is configured to detect a second signal generated between the second opposing fixed electrode 52AE and the second opposing beam electrode 32AE. A capacitance (first signal) between the first opposing fixed electrode 51AE and the first opposing beam electrode 31AE changes according to the vibration of the first beam 31. A change in the resonance frequency of the first beam 31 can be detected by detecting the first signal. A capacitance (second signal) between the second opposing fixed electrode 52AE and the second opposing beam electrode 32AE changes according to the vibration of the second beam 32. A change in the resonance frequency of the second beam 32 can be detected by detecting the second signal.

The controller 70 may output a signal corresponding to the difference between the first signal and the second signal. By differential processing, more accurate detection can be performed. For example, high detection results with suppressed temperature dependence can be obtained.

As shown in FIG. 1, the element section 10E may include a movable member 20M. As shown in FIG. 3D, the movable member 20M is supported by the first fixed portion 10S. In this example, the first support portion 28S includes a third support region 28c. In this example, the movable member 20M is supported by the third support region 28c.

The movable member 20M includes a first movable portion 21a. The first other portion 31b and the second other portion 32b are connected to the first movable portion 21a.

As shown in FIG. 4, the movable member 20M includes a first movable base portion 21B, a first movable intermediate portion 21M, and a first movable connecting portion 21C. The first movable base portion 21B is supported by the first fixed portion 10S. The first movable base portion 21B is supported by, for example, the third support region 28c.

The first movable intermediate portion 21M is provided between the first movable base portion 21B and the first movable portion 21a. The first movable connecting portion 21C is provided between the first movable base portion 21B and the first movable intermediate portion 21M. The first movable connecting portion 21C connects the first movable intermediate portion 21M with the first movable base portion 21B.

As shown in FIG. 4, a first movable connecting portion width w21C of the first movable connecting portion 21C in the second direction D2 is narrower than a first movable base portion width w21B of the first movable base portion 21B in the second direction D2. The first movable connecting portion width w21C is narrower than a first movable intermediate portion width w21M of the first movable intermediate portion 21M in the second direction D2. The first movable connecting portion 21C function as a pivot portion, for example. The first movable intermediate portion 21M and the first movable portion 21a are easy to move. A force is amplified. Amplified stress is applied to the first beam 31 and the second beam 32. A large change occurs in the resonance frequency of the first beam 31 and the resonance frequency of the second beam 32.

As shown in FIG. 4, a first movable portion width w21a of the first movable portion 21a in the second direction D2 is wider than the first movable connecting portion width w21C. The first movable portion 21a functions as a weight portion.

As shown in FIG. 1, in this example, the first opposing beam electrode 31AE includes a first opposing extending portion 31AEx and a first opposing extending connecting portion 31AEc. The first opposing extending portion 31AEx extends along the first direction D1. The first opposing extending connecting portion 31AEc connects the first opposing extending portion 31AEx to the first intermediate portion 31c. The first opposing extending connecting portion 31AEc extends, for example, along the second direction D2.

In this example, the second opposing beam electrode 32AE includes a second opposing extending portion 32AEx and a second opposing extending connecting portion 32AEc. The second opposing extending portion 32AEx extends along the first direction D1. The second opposing extending connecting portion 32AEc connects the second opposing extending portion 32AEx to the second intermediate portion 32c. The second opposing extending connecting portion 32AEc extends, for example, along the second direction D2.

FIGS. 5A to 5D are schematic cross-sectional views illustrating a sensor according to the first embodiment.

FIGS. 5A to 5D are cross-sectional views corresponding to the lines A1-A2, A5-A6, A7-A8, and A11-A12 in FIG. 1.

In a sensor 110a according to the embodiment, a mass of the second beam electrode 32E is different from a mass of the first beam electrode 31E. In the sensor 110a, a mass of the second opposing beam electrode 32AE differs from a mass of the first opposing beam electrode 31AE. In the sensor 110a, the two beams have different resonance characteristics (resonance frequencies).

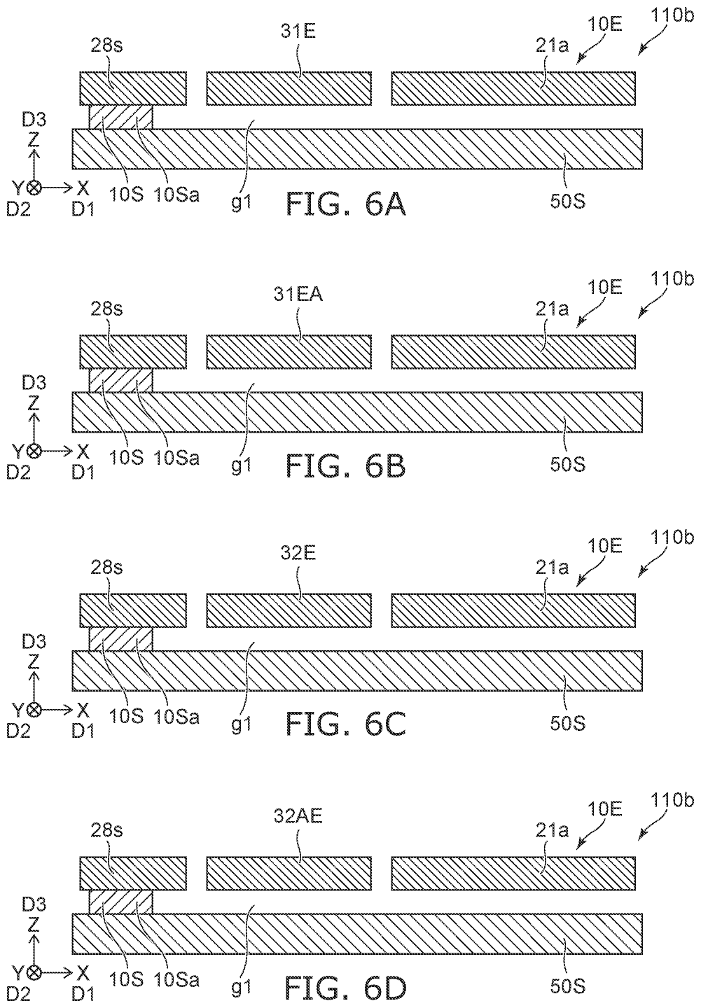

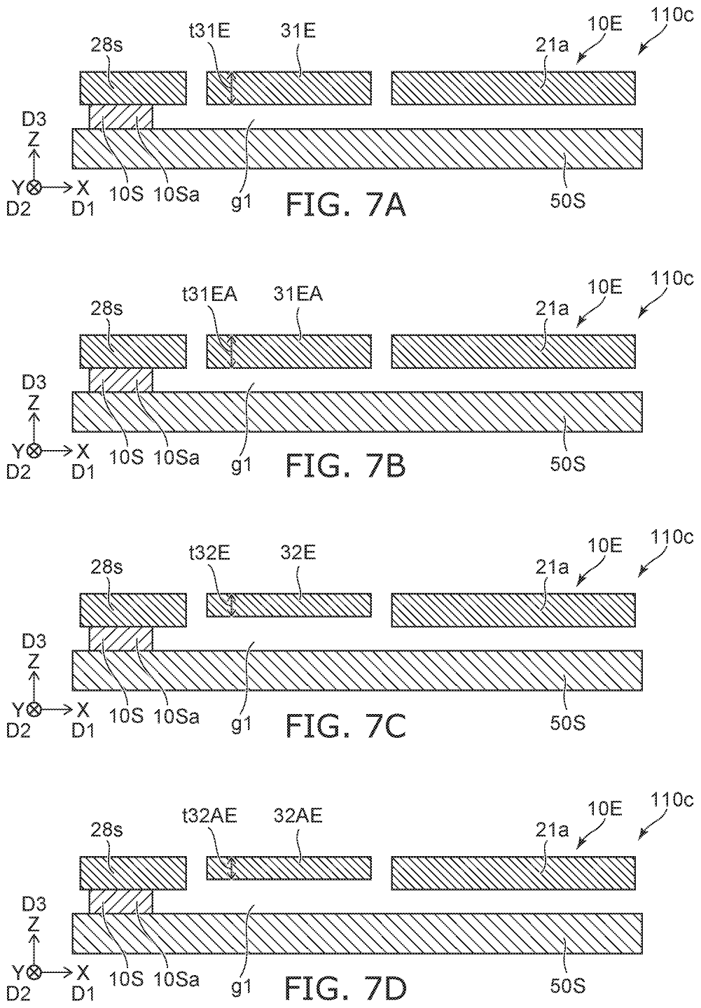

FIGS. 6A to 6D are schematic cross-sectional views illustrating a sensor according to the first embodiment.

FIGS. 6A to 6D are cross-sectional views corresponding to the lines A1-A2, A5-A6, A7-A8, and A11-A12 in FIG. 1.

In a sensor 110b according to the embodiment, at least a part of a material of the second beam electrode 32E is different from at least a part of a material of the first beam electrode 31E. In the sensor 110b, at least a part of a material of the second opposing beam electrode 32AE is different from at least a part of a material of the first opposing beam electrode 31AE. In the sensor 110b, the two beams have different resonance characteristics (resonance frequencies).

FIGS. 7A to 7D are schematic cross-sectional views illustrating a sensor according to the first embodiment.

FIGS. 7A to 7D are cross-sectional views corresponding to the lines A1-A2, A5-A6, A7-A8, and A11-A12 in FIG. 1.

In a sensor 110c according to the embodiment, a thickness along the third direction D3 of the second beam electrode 32E (second thickness t32E) is different from a thickness along the third direction D3 of the first beam electrode 31E (first thickness t31E). In the sensor 110c, a thickness along the third direction D3 of the second opposing beam electrode 32AE (second opposing thickness t32AE) is different from a thickness along the third direction D3 of the first beam electrode 31E (first thickness t31E). The two beams have different resonance characteristics (resonance frequency).

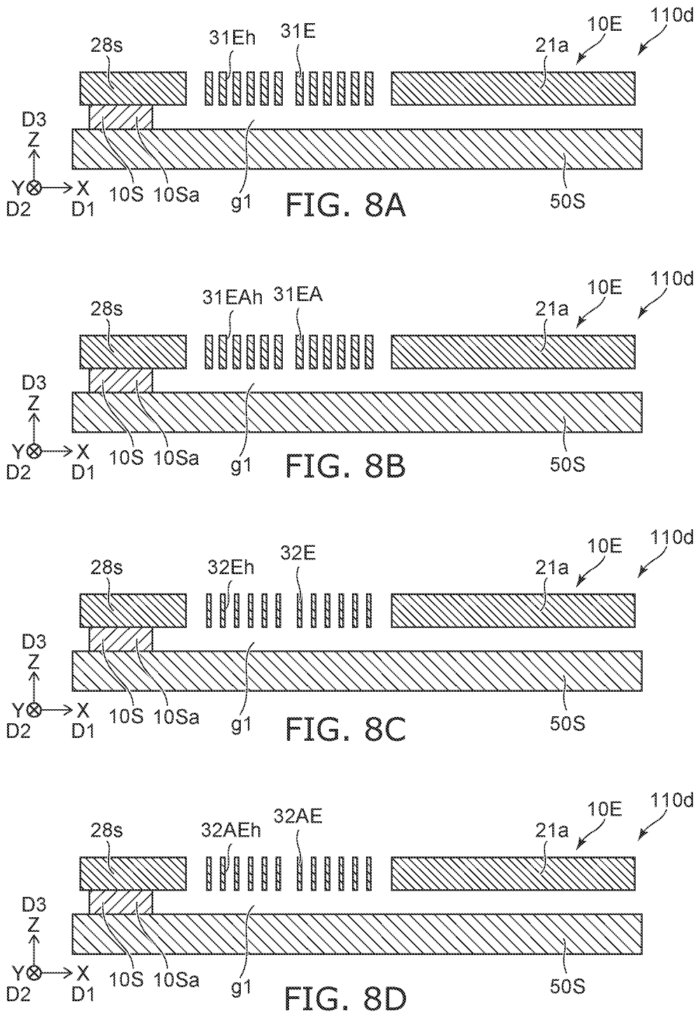

FIGS. 8A to 8D are schematic cross-sectional views illustrating a sensor according to the first embodiment.

FIGS. 8A to 8D are cross-sectional views corresponding to the lines A1-A2, A5-A6, A7-A8, and A11-A12 in FIG. 1.

In a sensor 110d according to the embodiment, a second size of the second hole 32Eh included in the second beam electrode 32E is different from a first size of the first hole 31Eh included in the first beam electrode 31E. In the sensor 110d, a second opposing size of a second opposing hole 32AEh included in the second opposing beam electrode 32AE is different from a first opposing size of a first opposing hole 31AEh included in the first opposing beam electrode 31AE. The two beams have different resonance characteristics (resonance frequencies).

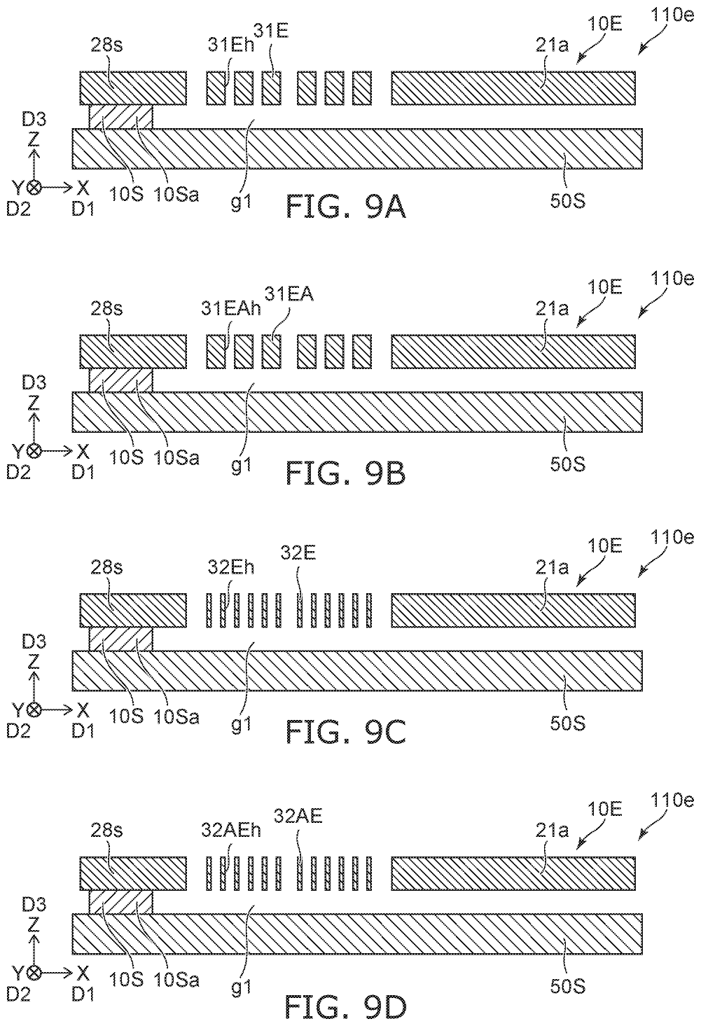

FIGS. 9A to 9D are schematic cross-sectional views illustrating a sensor according to the first embodiment.

FIGS. 9A to 9D are cross-sectional views corresponding to the lines A1-A2, A5-A6, A7-A8, and A11-A12 in FIG. 1.

In a sensor 110e according to the embodiment, a second density of the second holes 32Eh is different from a first density of the first holes 31Eh. In the sensor 110e, a second opposing density of the second opposing holes 32AEh is different from a first opposing density of the first opposing holes 31AEh. The two beams have different resonance characteristics (resonance frequencies).

In the sensor 110e, a second number of second holes 32Eh is different from a first number of first holes 31Eh. Alternatively, the second beam electrode 32E includes the second hole 32Eh and the first beam electrode 31E does not include the first hole 31Eh. In the sensor 110e, a second opposing number of the second opposing holes 32AEh is different from a first opposing number of the first opposing holes 31AEh. Alternatively, the second opposing beam electrode 32AE includes the second opposing hole 32AEh, and the first opposing beam electrode 31AE does not include the first opposing hole 31AEh. The two beams have different resonance characteristics (resonance frequencies).

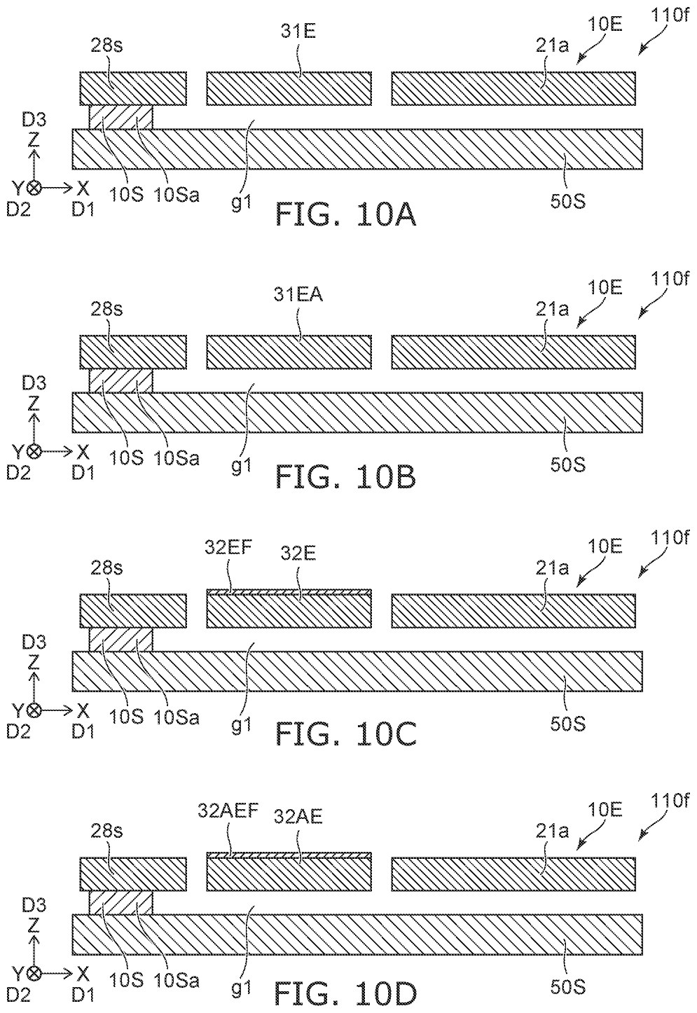

FIGS. 10A to 10D are schematic cross-sectional views illustrating the sensor according to the first embodiment.

FIGS. 10A to 10D are cross-sectional views corresponding to the lines A1-A2, A5-A6, A7-A8, and A11-A12 in FIG. 1.

In a sensor 110f according to the embodiment, a second layer structure of the second beam electrode 32E is different from a first layer structure of the first beam electrode 31E. In this example, the second beam electrode 32E includes a second beam layer 32EF and the first beam electrode 31E does not include the first beam layer. In the sensor 110f, a second opposing layer structure of the second opposing beam electrode 32AE is different from a first opposing layer structure of the first opposing beam electrode 31AE. In this example, the second opposing beam electrode 32AE includes a second opposing beam layer 32AEF, and the first opposing beam electrode 31AE does not include the first opposing beam layer. The two beams have different resonance characteristics (resonance frequencies). The second beam layer 32EF and the second opposing beam layer 32AEF may include, for example, a metal film.

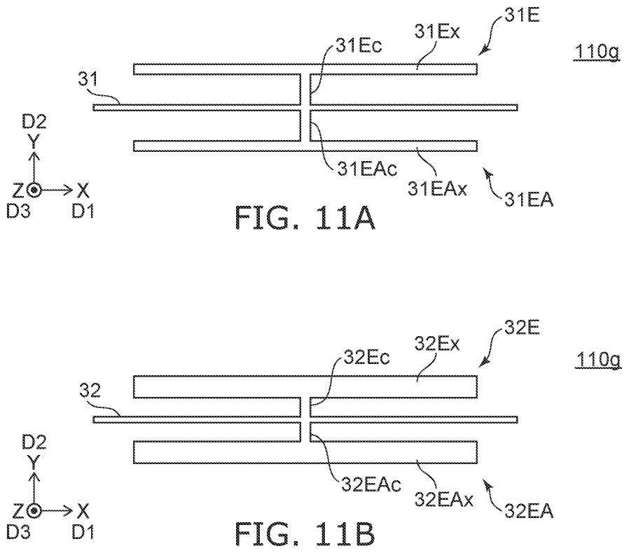

FIGS. 11A and 11B are schematic plan views illustrating a part of a sensor according to the first embodiment.

FIG. 11A illustrates a portion including the first beam 31. FIG. 11B illustrates a portion including the second beam 32.

In a sensor 110g according to the embodiment, a second shape of the second beam electrode 32E is different from a first shape of the first beam electrode 31E. In the sensor 110g, a second opposing shape of the second opposing beam electrode 32AE is different from a first opposing shape of the first opposing beam electrode 31AE. The two beams have different resonance characteristics (resonance frequencies). In this example, a ratio of a length of the second extending portion 32Ex in the second direction D2 to a length of the second extending portion 32Ex in the first direction D1 is higher than a ratio of a length of the first extending portion 31Ex in the second direction D2 to a length of the first extending portion 31Ex in the first direction D1. The difference in shape may include a difference between at least one of a protruding portion and a depression portion.

As described above, in the embodiment, the first beam electrode 31E and the second beam electrode 32E may satisfy at least one of a first condition, a second condition, a third condition, a fourth condition, a fifth condition, a sixth condition, a seventh condition or an eighth condition.

In the first condition, the second mass of the second beam electrode 32E is different from the first mass of the first beam electrode 31E. In the second condition, at least a part of the second material included in the second beam electrode 32E is different from at least a part of the first material included in the first beam electrode 31E. In the third condition, the second thickness t32E along the third direction D3 of the second beam electrode 32E is different from the first thickness t31E along the third direction D3 of the first beam electrode 31E. The third direction D3 crosses a plane including the first direction D1 and the second direction D2.

In the fourth condition, the second size of the second hole 32Eh included in the second beam electrode 32E is different from the first size of the first hole 31Eh included in the first beam electrode 31E. In the fifth condition, the second density of the second holes 32Eh is different from the first density of the first holes 31Eh.

In the sixth condition, the second number of second holes 32Eh is different from the first number of first holes 31Eh. Alternatively, in the sixth condition, the second beam electrode 32E includes the second hole 32Eh and the first beam electrode 31E does not include the first hole 31Eh.

In the seventh condition, the second layer structure of the second beam electrode 32E is different from the first layer structure of the first beam electrode 31E. In the eighth condition, the second shape of the second beam electrode 32E is different from the first shape of the first beam electrode 31E.

The first opposing beam electrode 31AE and the second opposing beam electrode 32AE may satisfy at least one of a ninth condition, a tenth condition, an eleventh condition, a twelfth condition, a thirteenth condition, a fourteenth condition, a fifteenth condition, or a sixteenth condition.

In the ninth condition, a second opposing mass of the second opposing beam electrode 32AE is different from a first opposing mass of the first opposing beam electrode 31AE. In the tenth condition, at least a part of a second opposing material included in the second opposing beam electrode 32AE is different from at least a part of a first opposing material included in the first opposing beam electrode 31AE. In the eleventh condition, a second opposing thickness t32AE along the third direction D3 of the second opposing beam electrode 32AE is different from a first opposing thickness t31AE along the third direction D3 of the first opposing beam electrode 31AE.

In the twelfth condition, the second opposing size of the second opposing hole 32AEh included in the second opposing beam electrode 32AE is different from the first opposing size of the first opposing hole 31AEh included in the first opposing beam electrode 31AE. In the thirteenth condition, the second opposing density of the second opposing holes 32AEh is different from the first opposing density of the first opposing holes 31AEh.

In the fourteenth condition, the second opposing number of the second opposing holes 32AEh is different from the first opposing number of the first opposing holes 31AEh. Alternatively, in the fourteenth condition, the second opposing beam electrode 32AE includes the second opposing hole 32AEh, and the first opposing beam electrode 31AE does not include the first opposing hole 31AEh.

In the fifteenth condition, the second opposing layer structure of the second opposing beam electrode 32AE is different from the first opposing layer structure of the first opposing beam electrode 31AE. In the sixteenth condition, the second opposing shape of the second opposing beam electrode 32AE is different from the first opposing shape of the first opposing beam electrode 31AE.

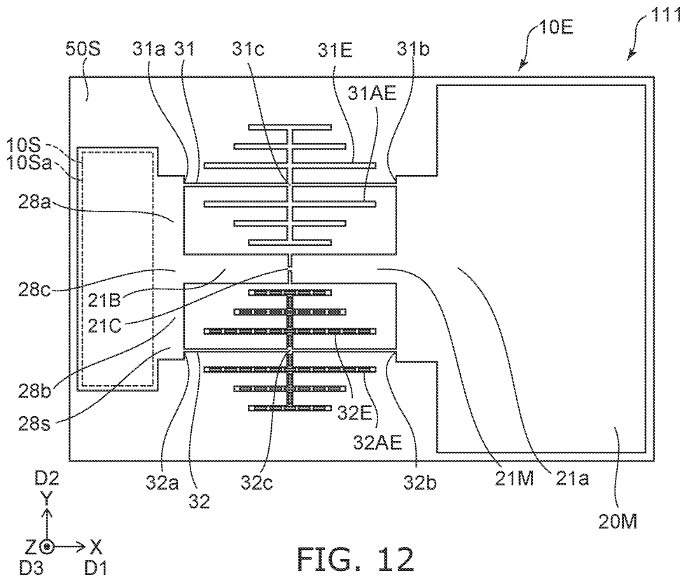

FIG. 12 is a schematic plan view illustrating a sensor according to the first embodiment.

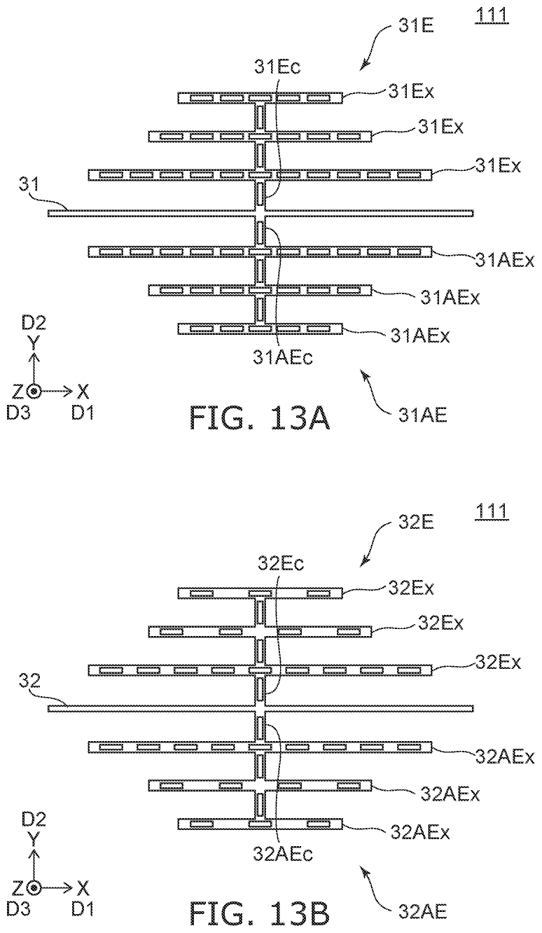

FIGS. 13A and 13B are schematic plan views illustrating the sensor according to the first embodiment.

As shown in FIG. 12, in a sensor 111 according to the embodiment, the shape of the first beam electrode 31E is different from the shape of the first beam electrode 31E in the sensor 110. In the sensor 111, the shape of the second beam electrodes 32E is different from the shape of the second beam electrodes 32E in the sensor 110. Except for this, the configuration of the sensor 111 may be the same as the configuration of the sensor 110. In FIG. 12, fixed electrodes are omitted.

As shown in FIG. 13A, in the sensor 111, the first beam electrode 31E includes a plurality of first extending portions 31Ex. One of the plurality of first extending portions 31Ex is provided between the first beam 31 and another one of the plurality of first extending portions 31Ex. For example, a length of the one of the plurality of first extending portions 31Ex along the first direction D1 is longer than a length of the other one of the plurality of first extending portions 31Ex along the first direction D1. By providing the plurality of first extending portions 31Ex, for example, the vibration of the first beam 31 can be effectively controlled with high accuracy.

As shown in FIG. 13B, in the sensor 111, the second beam electrode 32E includes a plurality of second extending portions 32Ex. One of the plurality of second extending portions 32Ex is provided between the second beam 32 and another one of the plurality of second extending portions 32Ex. For example, a length of the one of the plurality of second extending portions 32Ex along the first direction D1 is longer than a length of the other one of the plurality of second extending portions 32Ex along the first direction D1. By providing the plurality of second extending portions 32Ex, for example, the vibration of the second beam 32 can be effectively controlled with high accuracy.

As shown in FIG. 13A, in the sensor 111, the first opposing beam electrode 31AE includes a plurality of first opposing extending portions 31AEx. One of the plurality of first opposing extending portions 31AEx is provided between the first beam 31 and another one of the plurality of first opposing extending portions 31AEx. For example, a length of the one of the plurality of first opposing extending portions 31AEx along the first direction D1 is longer than a length of the other one of the plurality of first opposing extending portions 31AEx along the first direction D1. By providing the plurality of first opposing extending portions 31AEx, for example, the vibration characteristics of the first beam 31 can be effectively detected with high accuracy.

As shown in FIG. 13B, in the sensor 111, the second opposing beam electrode 32AE includes a plurality of second opposing extending portions 32AEx. One of the plurality of second opposing extending portions 32AEx is provided between the second beam 32 and another one of the plurality of second opposing extending portions 32AEx. For example, a length of the plurality of second opposing extending portions 32AEx along the first direction D1 is longer than a length of the other one of the plurality of second opposing extending portions 32AEx along the first direction D1. By providing the plurality of second opposing extending portions 32AEx, for example, the vibration characteristics of the second beam 32 can be effectively detected with high accuracy.

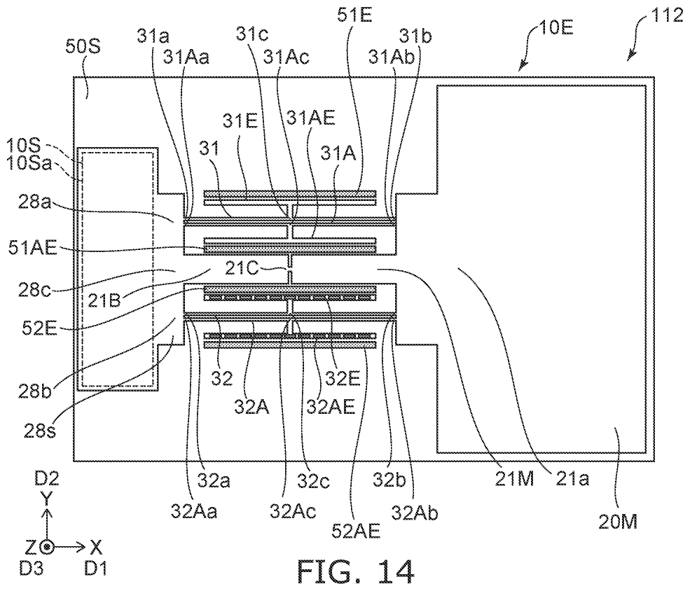

FIG. 14 is a schematic plan view illustrating a sensor according to the first embodiment.

As shown in FIG. 14, in a sensor 112 according to the embodiment, the element section 10E includes the first opposing beam 31A and the second opposing beam 32A. Except for this, the configuration of the sensor 112 may be the same as the configuration of the sensor 110.

In the sensor 112, the first opposing beam 31A includes a first opposing portion 31Aa, a first other opposing portion 31Ab, and a first opposing intermediate portion 31Ac. The first opposing intermediate portion 31Ac is provided between the first opposing portion 31Aa and the first other opposing portion 31Ab. A direction from the first opposing portion 31Aa to the first other opposing portion 31Ab is along the first direction D1. The first opposing beam electrode 31AE is connected to the first opposing intermediate portion 31Ac.

The second opposing beam 32A includes a second opposing portion 32Aa, a second other opposing portion 32Ab, and a second opposing intermediate portion 32Ac. The second opposing intermediate portion 32Ac is provided between the second opposing portion 32Aa and the second other opposing portion 32Ab. A direction from the second opposing portion 32Aa to the second other opposing portion 32Ab is along the first direction D1. The second opposing beam electrode 32AE is connected to the second opposing intermediate portion 32Ac.

In the sensor 112, for example, detection with high accuracy and wide a dynamic range is possible. A sensor capable of improving characteristics can be provided.

The first extending connecting portion 31Ec connects the first extending portion 31Ex to the first intermediate portion 31c. The second extending connecting portion 32Ec connects the second extending portion 32Ex to the second intermediate portion 32c. The first opposing extending connecting portion 31AEc connects the first opposing extending portion 31AEx to the first opposing intermediate portion 31Ac. The second opposing extending connecting portion 32AEc connects the second opposing extending portion 32AEx to the second opposing intermediate portion 32Ac.

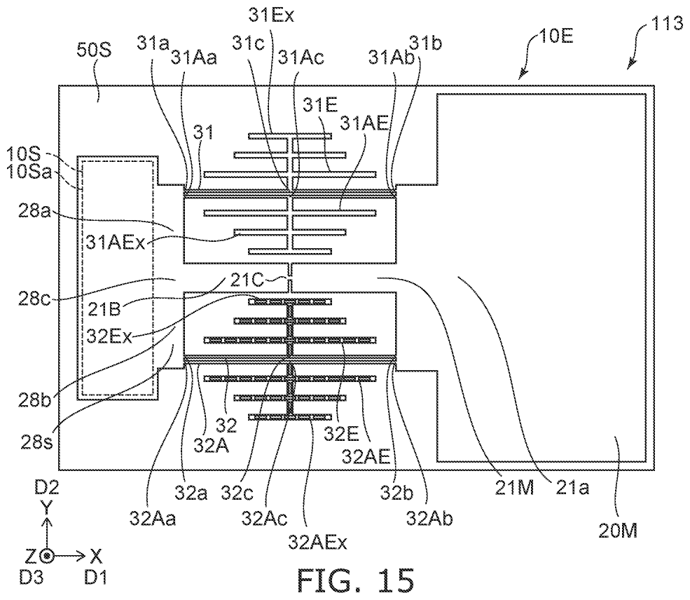

FIG. 15 is a schematic plan view illustrating a sensor according to the first embodiment.

As shown in FIG. 15, in a sensor 113 according to the embodiment, the plurality of first extending portions 31Ex, the plurality of second extending portions 32Ex, the plurality of first opposing extending portions 31AEx, and the plurality of second opposing extending portions 31AEx. Except for this, the configuration of the sensor 113 may be the same as the configuration of the sensor 112.

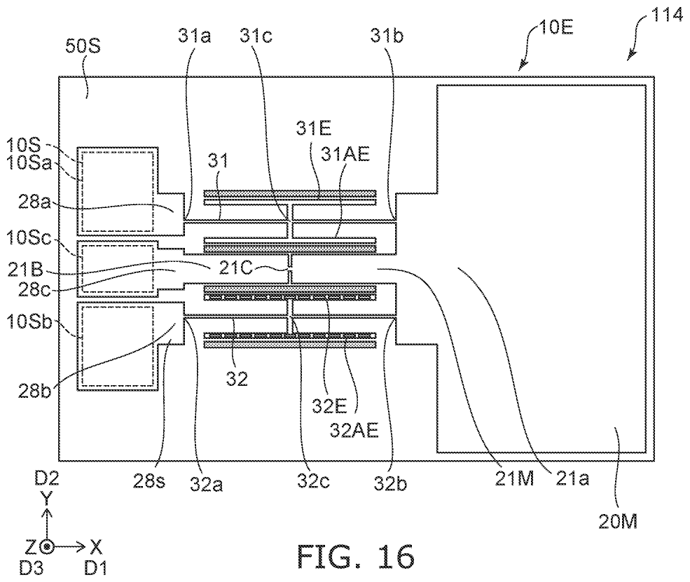

FIG. 16 is a schematic plan view illustrating the sensor according to the first embodiment.

As shown in FIG. 16, in a sensor 114 according to the embodiment, the first fixed portion 10S includes the first fixed region 10a, the second fixed region 10b, and the third fixed region 10c. Except for this, the configuration of the sensor 114 may be the same as the configuration of the sensor 110.

In the sensor 114, the first support region 28a is supported by first fixed region 10a. The second support region 28b is supported by the second fixed region 10b. The third support region 28c is supported by the third fixed region 10c.

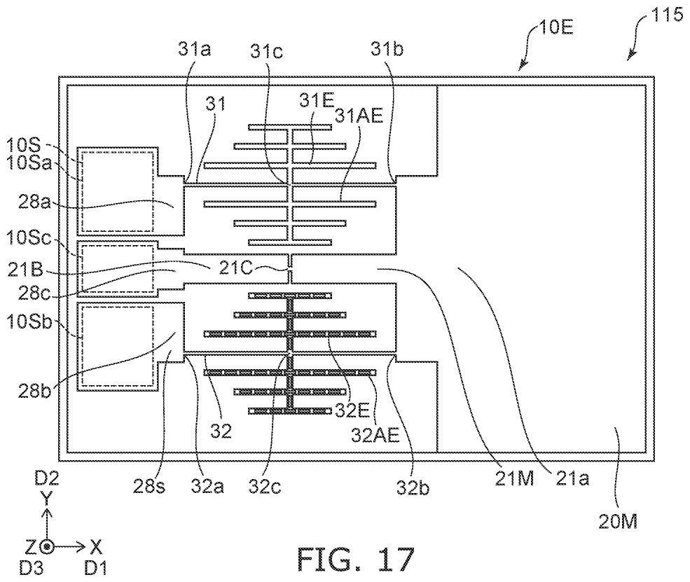

FIG. 17 is a schematic plan view illustrating a sensor according to the first embodiment.

As shown in FIG. 17, in a sensor 115 according to the embodiment, the first fixed portion 10S includes the first fixed region 10a, the second fixed region 10b, and the third fixed region 10c. Except for this, the configuration of the sensor 115 may be the same as the configuration of the sensor 111 or the sensor 114.

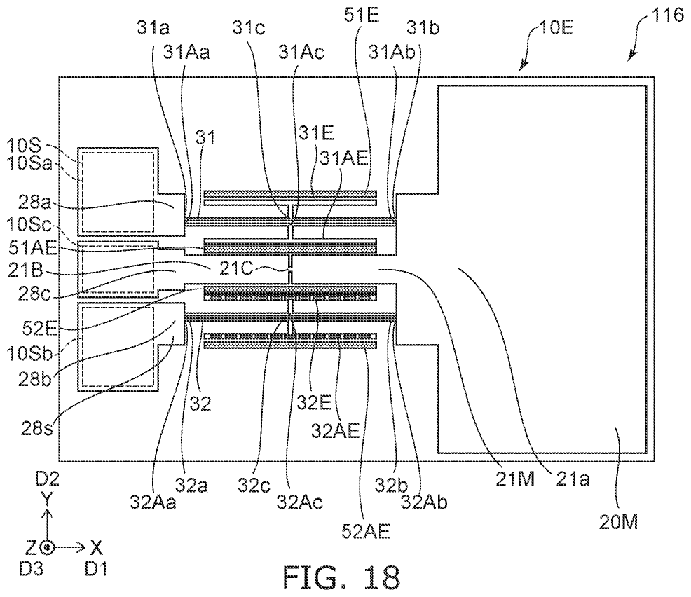

FIG. 18 is a schematic plan view illustrating a sensor according to the first embodiment.

As shown in FIG. 18, in a sensor 116 according to the embodiment, the first fixed portion 10S includes the first fixed region 10a, the second fixed region 10b, and the third fixed region 10c. Except for this, the configuration of sensor 116 may be the same as the configuration of sensor 112 or sensor 114.

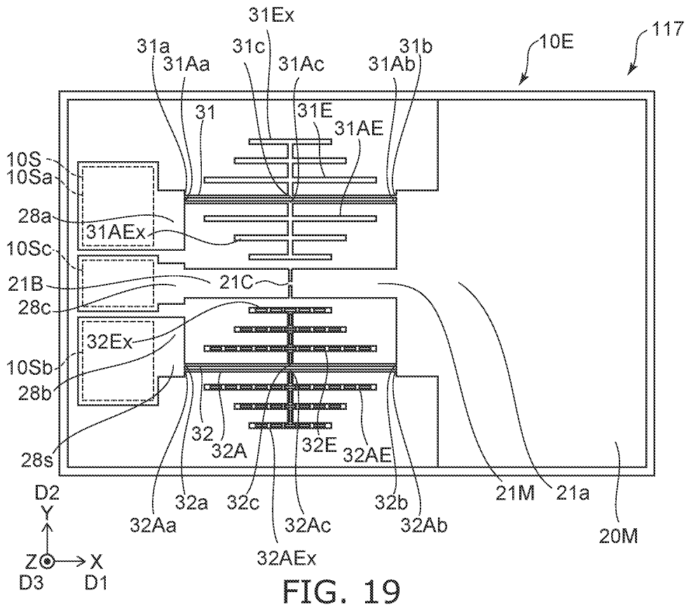

FIG. 19 is a schematic plan view illustrating a sensor according to the first embodiment.

As shown in FIG. 19, in a sensor 117 according to the embodiment, the first fixed portion 10S includes the first fixed region 10a, the second fixed region 10b, and the third fixed region 10c. Except for this, the configuration of the sensor 116 may be the same as the configuration of the sensor 113 or the sensor 114.

In the sensors 113-117, for example, detection with high accuracy and a wide dynamic range is possible. A sensor capable of improving characteristics can be provided.

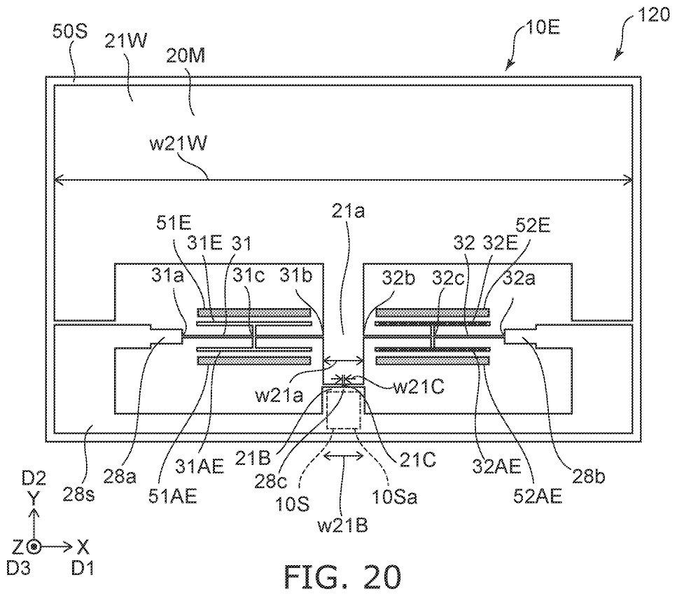

FIG. 20 is a schematic plan view illustrating a sensor according to the first embodiment.

As shown in FIG. 20, in a sensor 120 according to the embodiment, the configurations of the first beam 31 and the second beam 32 are different from those configurations in the sensor 110. Except for this, the configuration of the sensor 120 may be the same as the configuration of the sensor 110.

In the sensor 120, the position of the first other portion 31b in the first direction D1 is provided between the position of the first portion 31a in the first direction D1 and the position of the second portion 32a in the first direction D1. The position of the second other portion 32b in the first direction D1 is provided between the position of the first other portion 31b in the first direction D1 and the position of the second portion 32a in the second direction D2.

In the sensor 120, the element section 10E includes the movable member 20M. The movable member 20M is supported by the first fixed portion 10S. The movable member 20M includes the first movable portion 21a. The first other portion 31b and the second other portion 32b are connected to the first movable portion 21a. For example, in the first direction D1, the first movable portion 21a is provided between the first other portion 31b and the second other portion 32b.

The first support portion 28S includes the first support region 28a, the second support region 28b, and the third support region 28c. The first portion 31a is supported by the first support region 28a. The second portion 32a is supported by the second support region 28b. The first movable portion 21a is supported by the third support region 28c.

In this example, the movable member 20M includes the first movable base portion 21B supported by the third support region 28c, and the first movable connecting portion 21C provided between the first movable base portion 21B and the first movable portion 21a.

The first movable connecting portion width w21C of the first movable connecting portion 21C in the first direction D1 is narrower than the first movable base width w21B of the first movable base portion 21B in the first direction D1. The first movable connecting portion width w21C is narrower than the first movable portion width w21a of the first movable portion 21a in the first direction D1. The first movable connecting portion 21C function as a pivot part, for example. The applied force is amplified. The two beams are effectively stressed. Effectively, the resonance characteristics (e.g., resonance frequency) are changed in the two beams.

In this example, the movable member 20M further includes a first movable weight portion 21W connected to the first movable portion 21a. The first movable portion 21a is provided between the first movable connecting portion 21C and the first movable weight portion 21W in the second direction D2. A first movable weight portion width w21W in the first direction D1 of the first movable weight portion 21W is wider than the first movable portion width w21a. A larger stress is applied to the two beams by the first movable weight portion 21W.

In the sensor 120, the element section 10E is provided with the first beam electrode 31E and the second beam electrode 32E. The element section 10E may include the first opposing beam electrode 31AE and the second opposing beam electrode 32AE. The first opposing beam electrode 31AE is connected to the first intermediate portion 31c. The second opposing beam electrode 32AE is connected to the second intermediate portion 32c. The first beam 31 is provided between the first opposing beam electrode 31AE and the first beam electrode 31E in the second direction D2. The second beam 32 is provided between the second opposing beam electrode 32AE and the second beam electrode 32E in the second direction D2.

In the sensor 120, at least any one of the first to eighth conditions described above may be applied. In the sensor 120, at least one of the ninth to sixteenth conditions described above may be applied. In the sensor 120, for example, detection with high accuracy and a wide dynamic range is possible. A sensor capable of improving characteristics can be provided.

Also in the sensor 120, the first beam electrode 31E includes the first extending portion 31Ex and the first extending connecting portion 31Ec (see FIG. 11A). The second beam electrode 32E includes the second extending portion 32Ex and the second extending connecting portion 32Ec (see FIG. 11B). The first opposing beam electrode 31AE includes the first opposing extending portion 31AEx and the first opposing extending connecting portion 31AEc (see FIG. 11A). The second opposing beam electrode 32AE includes the second opposing extending portion 32AEx and the second opposing extending connecting portion 32AEc (see FIG. 11B).

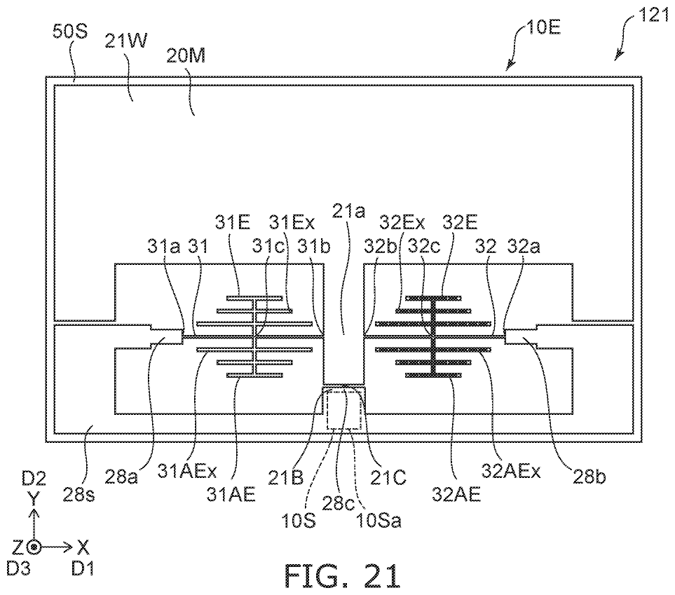

FIG. 21 is a schematic plan view illustrating a sensor according to the first embodiment.

As shown in FIG. 21, in a sensor 121 according to the embodiment, the element section 10E includes the plurality of first extending portions 31Ex, the plurality of second extending portions 32Ex, the plurality of first opposing extending portions 31AEx, and the plurality of second opposing extending portions 32AEx. Except for this, the configuration of the sensor 121 may be the same as the configuration of the sensor 120.

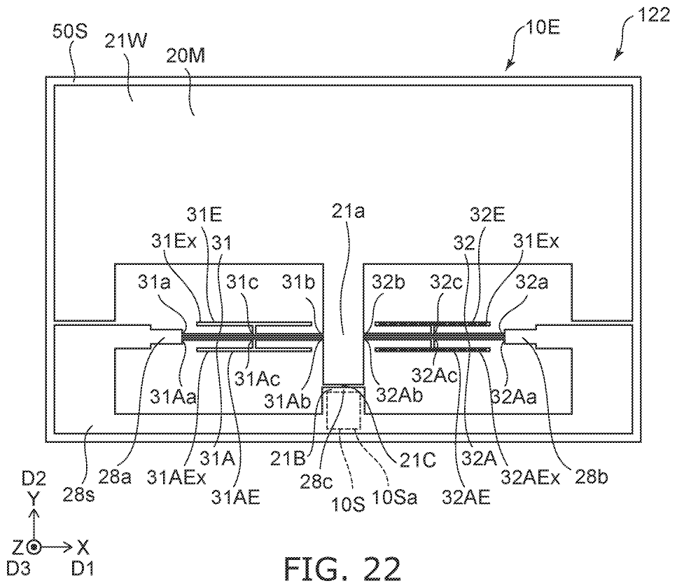

FIG. 22 is a schematic plan view illustrating a sensor according to the first embodiment.

As shown in FIG. 22, in the sensor 122 according to the embodiment, the first opposing beam 31A and the second opposing beam 32A are provided. Except for this, the configuration of the sensor 122 may be the same as the configuration of the sensor 120.

In the sensor 122, the element section 10E includes the first opposing beam 31A, the first opposing beam electrode 31AE, the second opposing beam 32A, and the second opposing beam electrode 32AE. As already explained, the first opposing beam 31A includes the first opposing portion 31Aa, the first other opposing portion 31Ab, and the first opposing intermediate portion 31Ac. The direction from the first opposing portion 31Aa to the first other opposing portion 31Ab is along the first direction D1. The first opposing beam electrode 31AE is connected to the first opposing intermediate portion 31Ac.

The second opposing beam 32A includes the second opposing portion 32Aa, the second other opposing portion 32Ab, and the second opposing intermediate portion 32Ac. The direction from the second opposing portion 32Aa to the second other opposing portion 32Ab is along the first direction D1. The second opposing beam electrode 32AE is connected to the second opposing intermediate portion 32Ac.

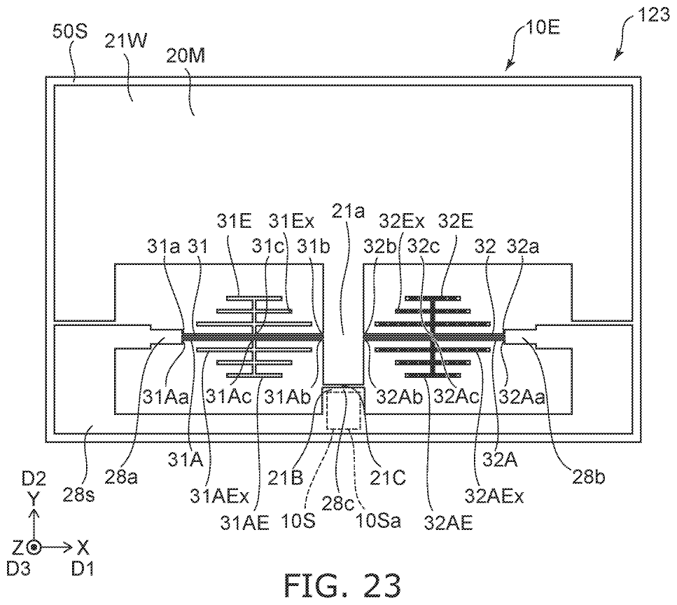

FIG. 23 is a schematic plan view illustrating a sensor according to the first embodiment.

As shown in FIG. 23, in a sensor 123 according to the embodiment, the element section 10E includes the plurality of first extending portions 31Ex, the plurality of second extending portions 32Ex, the plurality of first opposing extending portions 31AEx, and the plurality of second opposing extending portions 32AEx. Except for this, the configuration of the sensor 123 may be the same as the configuration of the sensor 122.

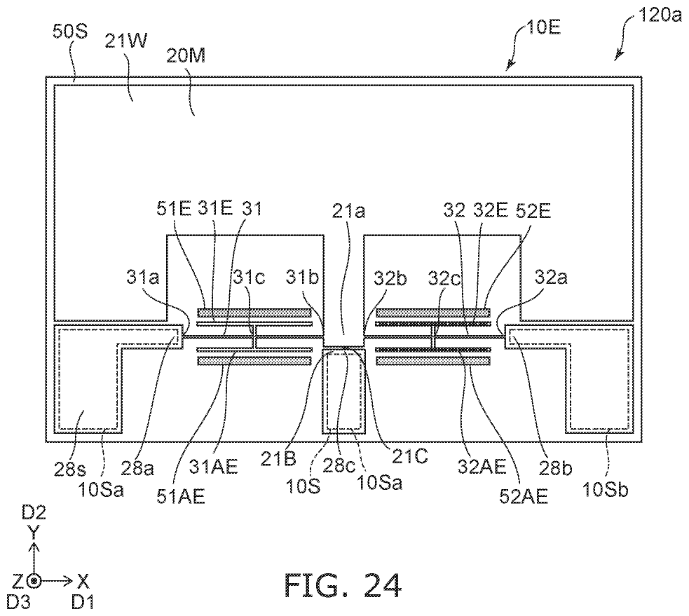

FIG. 24 is a schematic plan view illustrating a sensor according to the first embodiment.

As shown in FIG. 24, in a sensor 120a according to the embodiment, the first fixed portion 10S includes the first fixed region 10a, the second fixed region 10b, and the third fixed region 10c. Except for this, the configuration of the sensor 120a may be the same as the configuration of the sensor 120.

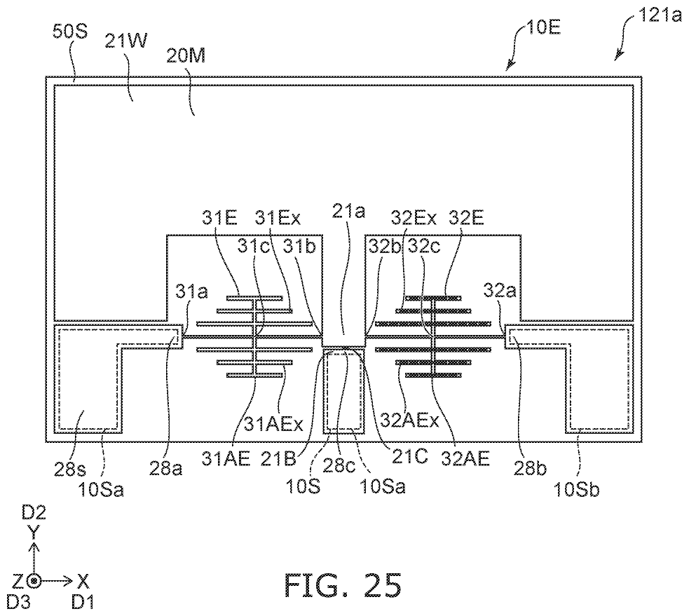

FIG. 25 is a schematic plan view illustrating a sensor according to the first embodiment.

As shown in FIG. 25, in a sensor 121a according to the embodiment, the first fixed portion 10S includes the first fixed region 10a, the second fixed region 10b, and the third fixed region 10c. Except for this, the configuration of the sensor 121a may be the same as the configuration of the sensor 121.

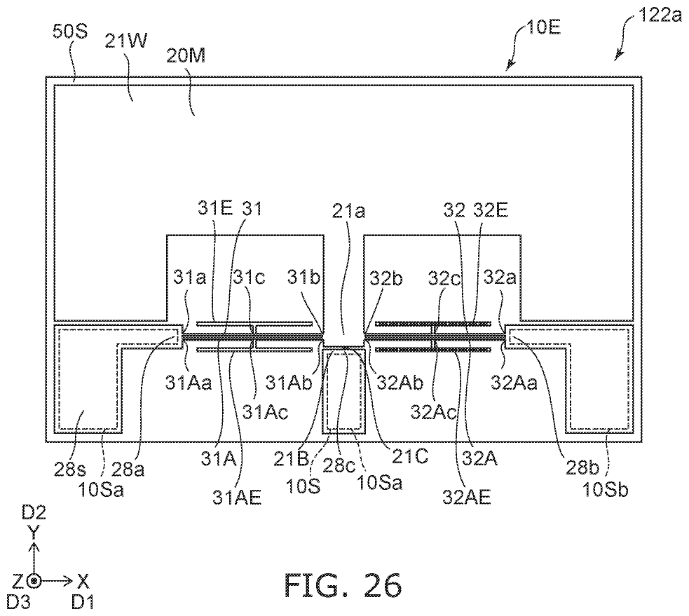

FIG. 26 is a schematic plan view illustrating a sensor according to the first embodiment.

As shown in FIG. 26, in a sensor 122a according to the embodiment, the first fixed portion 10S includes the first fixed region 10a, the second fixed region 10b, and the third fixed region 10c. Except for this, the configuration of the sensor 122a may be the same as the configuration of the sensor 122.

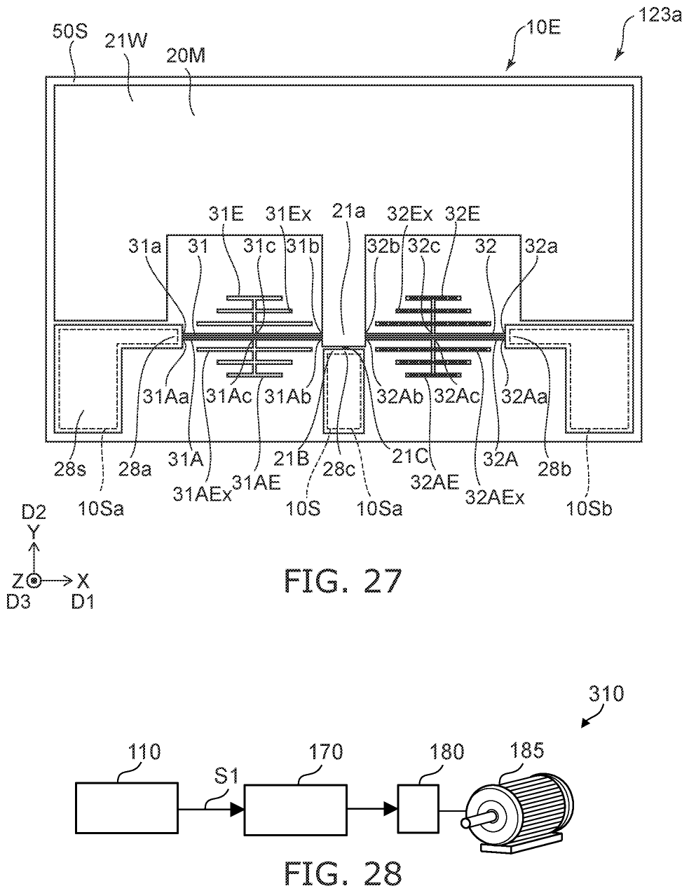

FIG. 27 is a schematic plan view illustrating a sensor according to the first embodiment.

As shown in FIG. 27, in a sensor 123a according to the embodiment, the first fixed portion 10S includes the first fixed region 10a, the second fixed region 10b, and the third fixed region 10c. Except for this, the configuration of the sensor 123a may be the same as the configuration of the sensor 123.

In the sensors 121 to 123 and the sensors 120a to 123a, for example, detection with high accuracy and a wide dynamic range is possible. A sensor capable of improving characteristics can be provided.

### Second Embodiment

The second embodiment relates to an electronic device.

FIG. 28 is a schematic diagram illustrating an electronic device according to the second embodiment.

As shown in FIG. 28, an electronic device 310 according to the embodiment includes the sensor according to the first embodiment and a circuit controller 170. In the example of FIG. 28, the sensor 110 is drawn as the sensor. The circuit controller 170 is configured to control a circuit 180 based on a signal S1 obtained from the sensor. The circuit 180 is, for example, a control circuit of a driving device 185 or the like. According to the embodiment, for example, the circuit 180 for controlling the driving device 185 can be controlled with high accuracy.

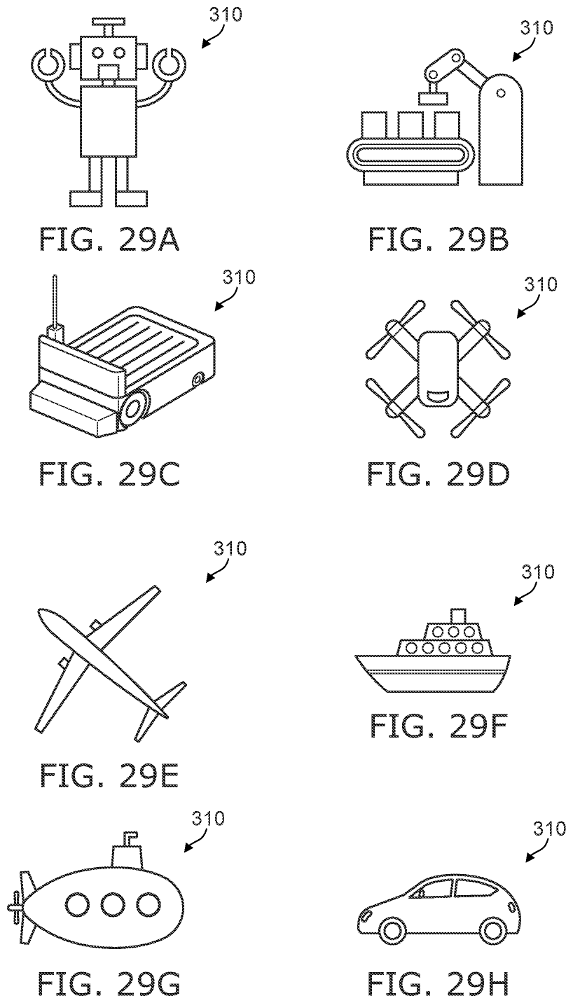

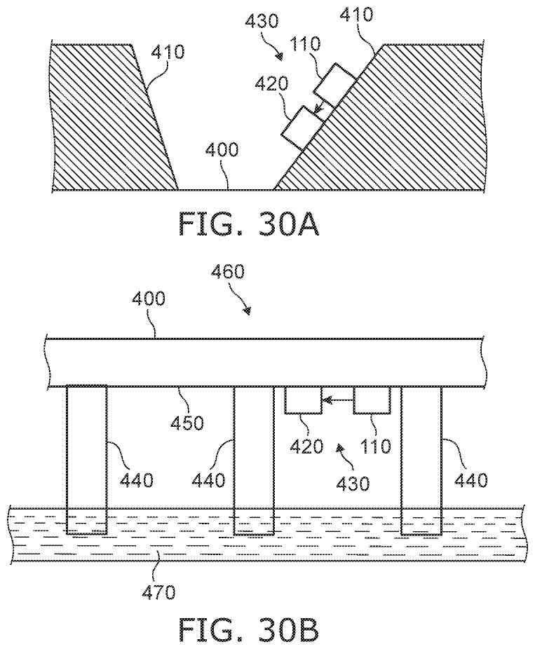

FIGS. 29A to 29H are schematic diagrams illustrating applications of the electronic device according to the embodiment.

As shown in FIG. 29A, the electronic device 310 may be at least a part of a robot. As shown in FIG. 29B, the electronic device 310 may be at least a part of a work robot provided in a manufacturing factory or the like. As shown in FIG. 29C, the electronic device 310 may be at least a part of an automated guided vehicle such as in a factory. As shown in FIG. 29D, the electronic device 310 may be at least a part of a drone (unmanned aerial vehicle). As shown in FIG. 29E, the electronic device 310 may be at least a part of an airplane. As shown in FIG. 29F, the electronic device 310 may be at least a part of a vessel. As shown in FIG. 29G, the electronic device 310 may be at least a part of a submarine. As shown in FIG. 29H, the electronic device 310 may be at least a part of an automobile. The electronic device 310 may include, for example, at least one of a robot or a mobile object.

FIGS. 30A and 30B are schematic diagrams illustrating applications of the sensor according to the embodiment.

As shown in FIG. 30A, a sensor 430 according to the embodiment includes the sensor according to the first embodiment and a transmitter/receiver 420. In the example of FIG. 30A, the sensor 110 is drawn as the sensor. The transmitter/receiver 420 is configured to transmit the signal obtained from the sensor 110 by at least one of wireless or wired methods, for example. The sensor 430 is provided, for example, on a slope surface 410 such as a road 400. The sensor 430 may, for example, monitor conditions such as facilities (e.g., infrastructure). The sensor 430 may be, for example, a condition monitoring device.

For example, the sensor 430 detects changes in the state of the slope surface 410 of the road 400 with high accuracy. A change in the state of the slope surface 410 includes, for example, at least one of a change in tilt angle or a change in vibration state. The signal (test result) obtained from the sensor 110 is transmitted by the transmitter/receiver 420. The condition of facilities (e.g., infrastructure) can be monitored, e.g., continuously.

As shown in FIG. 30B, the sensor 430 is provided on a part of a bridge 460, for example. The bridge 460 is provided over a river 470. For example, the bridge 460 includes at least one of main girder 450 and a bridge pier 440. The sensor 430 is provided on at least one of the main girder 450 and the bridge pier 440. For example, the angle of at least one of the main girder 450 and the bridge pier 440 may change due to deterioration or the like. For example, in at least one of the main girder 450 and the bridge pier 440, the vibration state may change. The sensor 430 detects these changes with high accuracy. A detection result can be transmitted to an arbitrary place by the transmitter/receiver 420. Anomalies can be effectively detected.

The embodiments include the following configurations (for example, technical proposals).

### Configuration 1

A sensor, comprising:
an element section including
   a first beam including a first portion, a first other portion, and a first intermediate portion between the first portion and the first other portion, a direction from the first portion to the first other portion being along a first direction;
   a first beam electrode connected to the first intermediate portion;
   a second beam including a second portion, a second other portion, and a second intermediate portion between the second portion and the second other portion, a direction from the second portion to the second other portion being along the first direction; and
   a second beam electrode connected to the second intermediate portion;
a second direction from the first intermediate portion to the first beam electrode crossing the first direction,
a direction from the second intermediate portion to the second beam electrode being along the second direction,
the first beam electrode and the second beam electrode satisfying at least one of a first condition, a second condition, a third condition, a fourth condition, a fifth condition, a sixth condition, a seventh condition or an eighth condition,
in the first condition, a second mass of the second beam electrode being different from a first mass of the first beam electrode,
in the second condition, at least a part of a second material included in the second beam electrode being different from at least a part of a first material included in the first beam electrode,
in the third condition, a second thickness of the second beam electrode along a third direction being different from a first thickness of the first beam electrode along the third direction, the third direction crossing a plane including the first direction and the second direction,
in the fourth condition, a second size of the second hole included in the second beam electrode being different from a first size of the first hole included in the first beam electrode,
in the fifth condition, a second density of the second holes being different from the first density of the first holes,
in the sixth condition, a second number of the second holes being different from a first number of the first holes, or the second beam electrode including the second holes and the first beam electrode not including the first hole,
in the seventh condition, a second layer structure of the second beam electrode being different from a first layer structure of the first beam electrode, and
in the eighth condition, a second shape of the second beam electrode being different from a first shape of the first beam electrode.

### Configuration 2

The sensor according to Configuration 1, further including:
a base; and
a first fixed portion fixed to the base,
the element section further including a first support portion supported by the first fixed portion,
a direction from the base to the first fixed portion being along the third direction,
the first portion and the second portion being connected to the first support portion, and
a first gap being provided between the base and the element section.

### Configuration 3

The sensor according to Configuration 2, wherein
a direction from the second beam to the first beam is along the second direction.

### Configuration 4

The sensor according to Configuration 3, wherein
the element section further includes a movable member supported by the first fixed portion,
the movable member includes a first movable portion, and
the first other portion and the second other portion are connected to the first movable portion.

### Configuration 5

The sensor according to Configuration 4, wherein
the movable member further includes
   a first movable base portion supported by the first fixed portion,
   a first movable intermediate portion provided between the first movable base portion and the first movable portion, and
   a first movable connecting portion provided between the first movable base portion and the first movable intermediate portion,
a first movable connecting portion width of the first movable connecting portion in the second direction is narrower than a first movable base portion width of the first movable base portion in the second direction, and
the first movable connecting portion width is narrower than a first movable intermediate portion width of the first movable intermediate portion in the second direction.

### Configuration 6

The sensor according to any one of Configurations 3-5, wherein
the first beam electrode includes
   a first extending portion extending along the first direction, and
   a first extending connecting portion connecting the first extending portion to the first intermediate portion, and
the second beam electrode includes
   a second extending portion along the first direction, and
   a second extending connecting portion connecting the second extending portion to the second intermediate portion.

### Configuration 7

The sensor according to Configuration 6, wherein
the first beam electrode includes a plurality of the first extending portions,
one of the plurality of first extending portions is provided between the first beam and another one of the plurality of first extending portions,
a length of the one of the plurality of first extending portions along the first direction is longer than a length of the other one of the plurality of first extending portions along the first direction,
the second beam electrode includes a plurality of the second extending portions,
one of the plurality of second extending portions is provided between the second beam and another one of the plurality of second extending portions, and
a length of the one of the plurality of second extending portions along the first direction is longer than a length of the other one of the plurality of second extending portions along the first direction.

### Configuration 8

The sensor according to Configuration 3, wherein
the element portion includes
   a first opposing beam electrode connected to the first intermediate portion, and
   a second opposing beam electrode connected to the second intermediate portion,
the first beam is provided between the first opposing beam electrode and the first beam electrode in the second direction, and
the second beam is provided between the second opposing beam electrode and the second beam electrode in the second direction.

### Configuration 9

The sensor according to Configuration 3, wherein
the element section includes
a first opposing beam including a first opposing portion, a first other opposing portion, and a first opposing intermediate portion between the first opposing portion and the first other opposing portion, a direction from the first opposing portion to the first other opposing portion being along the first direction,
a first opposing beam electrode connected to the first opposing intermediate portion,
a second opposing beam including a second opposing portion, a second other opposing portion, and a second opposing intermediate portion between the second opposing portion and the second other opposing portion, a direction from the second opposing portion to the second other opposing portion being along the first direction, and
a second opposing beam electrode connected to the second opposing intermediate portion.

### Configuration 10

The sensor according to Configuration 8 or 9, wherein
the first opposing beam electrode and the second opposing beam electrode satisfy at least one of a ninth condition, a tenth condition, an eleventh condition, a twelfth condition, a thirteenth condition, a fourteenth condition, a fifteenth condition or a sixteenth condition,
in the ninth condition, a second opposing mass of the second opposing beam electrode is different from the first opposing mass of the first opposing beam electrode,
in the tenth condition, at least a part of a second opposing material included in the second opposing beam electrode is different from at least a part of a first opposing material included in the first opposing beam electrode,
in the eleventh condition, a second opposing thickness along the third direction of the second opposing beam electrode is different from a first opposing thickness along the third direction of the first opposing beam electrode,
in the twelfth condition, a second opposing size of a second opposing hole included in the second opposing beam electrode is different from a first opposing size of a first opposing hole included in the first opposing beam electrode,
in the thirteenth condition, a second opposing density of the second opposing holes is different from a first opposing density of the first opposing holes,
in the fourteenth condition, a second opposing number of the second opposing holes is different from a first opposing number of the first opposing holes, or the second opposing beam electrode includes the second opposing hole and the first opposing beam electrode does not include the first opposing hole,
in the fifteenth condition, a second opposing layer structure of the second opposing beam electrode is different from a first opposing layer structure of the first opposing beam electrode, and
in the sixteenth condition, a second opposing shape of the second opposing beam electrode is different from a first opposing shape of the first opposing beam electrode.

### Configuration 11

The sensor according to Configuration 2, wherein
a position of the first other portion in the first direction is provided between a position of the first portion in the first direction and a position of the second portion in the first direction, and
a position of the second other portion in the first direction is provided between the position of the first other portion in the first direction and the position of the second portion in the second direction.

### Configuration 12

The sensor according to Configuration 11, wherein
the element section further includes a movable member supported by the first fixed portion,
the movable member includes a first movable portion,
the first other portion and the second other portion are connected to the first movable portion,
the first support portion includes a first support region, a second support region, and a third support region,
the first portion is supported by the first support region,
the second portion is supported by the second support region, and
the first movable part is supported by the third support

### Configuration 13

The sensor according to Configuration 12, wherein
the movable member further includes
   a first movable base portion supported by the third support region, and
   a first movable connecting portion provided between the first movable base portion and the first movable portion,
a first movable connecting portion width of the first movable connecting portion in the first direction is narrower than a first movable base width of the first movable base in the first direction, and
a first movable connecting portion width is narrower than a first movable portion width of the first movable portion in the first direction.

### Configuration 14

The sensor according to Configuration 13, wherein
the movable member further includes a first movable weight portion connected to the first movable portion,
the first movable portion is provided between the first movable connecting portion and the first movable weight portion in the second direction, and
a first movable weight portion width in the first direction of the first movable weight portion is wider than the first movable portion width.

### Configuration 15

The sensor according to any one of Configurations 11-14, wherein
the first beam electrode includes
   a first extending portion extending along the first direction, and
   a first extending connecting portion connecting the
first extending portion to the first intermediate portion, the second beam electrode includes
   a second extending portion extending along the second direction, and
   a second extending connecting portion connecting the second extending portion to the second intermediate portion.

### Configuration 16

The sensor according to Configuration 15, wherein
the first beam electrode includes a plurality of the first extending portions,
one of the plurality of first extending portions is provided between the first beam and another one of the plurality of first extending portions,
a length of the plurality of first extending portions along the first direction is longer than a length of the other one of the plurality of first extending portions along the first direction,
the second beam electrode includes a plurality of the second extending portions,
one of the plurality of second extending portions is provided between the second beam and another one of the plurality of second extending portions, and
a length of the one of the plurality of second extending portions along the first direction is longer than a length of the other one of the plurality of second extending portions along the first direction.

### Configuration 17

The sensor according to Configuration 11, wherein
the element section includes
   a first opposing beam electrode connected to the first intermediate portion, and
   a second opposing beam electrode connected to the second intermediate portion,
the first beam is provided between the first opposing beam electrode and the first beam electrode in the second direction, and
the second beam is provided between the second opposing beam electrode and the second beam electrode in the second direction.

### Configuration 18

The sensor according to Configuration 11, wherein
the element section includes
a first opposing beam including a first opposing portion, a first other opposing portion, and a first opposing intermediate portion between the first opposing portion and the first other opposing portion, a direction from the first opposing portion to the first other opposing portion being along the first direction,
a first opposing beam electrode connected to the first opposing intermediate portion,
a second opposing beam including a second opposing portion, a second other opposing portion, and a second opposing intermediate portion between the second opposing portion and the second other opposing portion, a direction from the second opposing portion to the second other opposing portion being along the first direction, and
a second opposing beam electrode connected to the second opposing intermediate portion.

### Configuration 19

The sensor according to any one of Configurations 2-17, further comprising:
a controller; and
a first fixed electrode and a second fixed electrode fixed to the base,
the first fixed electrode facing the first beam electrode,
the second fixed electrode facing the second beam electrode,
the controller being configured to apply a first AC signal between the first fixed electrode and the first beam electrode, and
the controller being configured to apply the first AC signal between the second fixed electrode and the second beam electrode.

### Configuration 20

An electronic device, comprising:
the sensor according to any one of Configurations 1-19; and
a circuit controller configured to control a circuit based on a signal obtained from the sensor.

### Configuration 21

The sensor according to Configuration 18 or 19, wherein
the first opposing beam electrode and the second opposing beam electrode satisfy at least one of a ninth condition, a tenth condition, an eleventh condition, a twelfth condition, a thirteenth condition, a fourteenth condition, a fifteenth condition or a sixteenth condition,
in the ninth condition, a second opposing mass of the second opposing beam electrode is different from a first opposing mass of the first opposing beam electrode,
in the tenth condition, at least a part of a second opposing material included in the second opposing beam electrode is different from at least a part of a first opposing material included in the first opposing beam electrode,
in the eleventh condition, a second opposing thickness of the second opposing beam electrode along the third direction is different from a first opposing thickness of the first opposing beam electrode along the third direction,
in the twelfth condition, a second opposing size of a second opposing hole included in the second opposing beam electrode is different from a first opposing size of a first opposing hole included in the first opposing beam electrode,
in the thirteenth condition, a second opposing density of the second opposing holes is different from a first opposing density of the first opposing holes,
in the fourteenth condition, a second opposing number of the second opposing holes is different from a first opposing number of the first opposing holes, or the second opposing beam electrode includes the second opposing holes and the first opposing beam electrode does not include the first opposing hole,
in the fifteenth condition, a second opposing layer structure of the second opposing beam electrode is different from a first opposing layer structure of the first opposing beam electrode, and
in the sixteenth condition, a second opposing shape of the second opposing beam electrode is different from a first opposing shape of the first opposing beam electrode.

According to the embodiments, a sensor and an electronic devices capable of enhanced properties can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in sensors such as bases, support portions, element sections, controllers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all sensors and electronic devices practicable by an appropriate design modification by one skilled in the art based on the sensors and the electronic devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A sensor, comprising:
an element section including
a first beam including a first portion, a first other portion, and a first intermediate portion between the first portion and the first other portion, a direction from the first portion to the first other portion being along a first direction;
a first beam electrode connected to the first intermediate portion;
a second beam including a second portion, a second other portion, and a second intermediate portion between the second portion and the second other portion, a direction from the second portion to the second other portion being along the first direction; and
a second beam electrode connected to the second intermediate portion;
a second direction from the first intermediate portion to the first beam electrode crossing the first direction,
a direction from the second intermediate portion to the second beam electrode being along the second direction,
the first beam electrode and the second beam electrode satisfying at least one of a first condition, a second condition, a third condition, a fourth condition, a fifth condition, a sixth condition, a seventh condition or an eighth condition,
in the first condition, a second mass of the second beam electrode being different from a first mass of the first beam electrode,
in the second condition, at least a part of a second material included in the second beam electrode being different from at least a part of a first material included in the first beam electrode,
in the third condition, a second thickness of the second beam electrode along a third direction being different from a first thickness of the first beam electrode along the third direction, the third direction crossing a plane including the first direction and the second direction,
in the fourth condition, a second size of a second hole included in the second beam electrode being different from a first size of a first hole included in the first beam electrode,
in the fifth condition, a second density of the second holes being different from the first density of the first holes,
in the sixth condition, a second number of the second holes being different from a first number of the first holes, or the second beam electrode including the second holes and the first beam electrode not including the first hole,
in the seventh condition, a second layer structure of the second beam electrode being different from a first layer structure of the first beam electrode, and
in the eighth condition, a second shape of the second beam electrode being different from a first shape of the first beam electrode.

2. The sensor according to claim 1, further including:
a base; and
a first fixed portion fixed to the base,
the element section further including a first support portion supported by the first fixed portion,
a direction from the base to the first fixed portion being along the third direction,
the first portion and the second portion being connected to the first support portion, and
a first gap being provided between the base and the element section.

3. The sensor according to claim 2, wherein
a direction from the second beam to the first beam is along the second direction.

4. The sensor according to claim 3, wherein
the element section further includes a movable member supported by the first fixed portion,
the movable member includes a first movable portion, and
the first other portion and the second other portion are connected to the first movable portion.

5. The sensor according to claim 4, wherein
the movable member further includes
a first movable base portion supported by the first fixed portion,
a first movable intermediate portion provided between the first movable base portion and the first movable portion, and
a first movable connecting portion provided between the first movable base portion and the first movable intermediate portion,
a first movable connecting portion width of the first movable connecting portion in the second direction is narrower than a first movable base portion width of the first movable base portion in the second direction, and
the first movable connecting portion width is narrower than a first movable intermediate portion width of the first movable intermediate portion in the second direction.

6. The sensor according to claim 3, wherein
the first beam electrode includes
a first extending portion extending along the first direction, and
a first extending connecting portion connecting the first extending portion to the first intermediate portion, and
the second beam electrode includes
a second extending portion along the first direction, and
a second extending connecting portion connecting the second extending portion to the second intermediate portion.

7. The sensor according to claim 6, wherein
the first beam electrode includes a plurality of the first extending portions,
one of the plurality of first extending portions is provided between the first beam and another one of the plurality of first extending portions,
a length of the one of the plurality of first extending portions along the first direction is longer than a length of the other one of the plurality of first extending portions along the first direction,
the second beam electrode includes a plurality of the second extending portions,
one of the plurality of second extending portions is provided between the second beam and another one of the plurality of second extending portions, and
a length of the one of the plurality of second extending portions along the first direction is longer than a length of the other one of the plurality of second extending portions along the first direction.

8. The sensor according to claim 3, wherein
the element portion includes
a first opposing beam electrode connected to the first intermediate portion, and
a second opposing beam electrode connected to the second intermediate portion,
the first beam is provided between the first opposing beam electrode and the first beam electrode in the second direction, and
the second beam is provided between the second opposing beam electrode and the second beam electrode in the second direction.

9. The sensor according to claim 3, wherein
the element section includes
a first opposing beam including a first opposing portion, a first other opposing portion, and a first opposing intermediate portion between the first opposing portion and the first other opposing portion, a direction from the first opposing portion to the first other opposing portion being along the first direction,
a first opposing beam electrode connected to the first opposing intermediate portion,
a second opposing beam including a second opposing portion, a second other opposing portion, and a second opposing intermediate portion between the second opposing portion and the second other opposing portion, a direction from the second opposing portion to the second other opposing portion being along the first direction, and
a second opposing beam electrode connected to the second opposing intermediate portion.

10. The sensor according to claim 8, wherein
the first opposing beam electrode and the second opposing beam electrode satisfy at least one of a ninth condition, a tenth condition, an eleventh condition, a twelfth condition, a thirteenth condition, a fourteenth condition, a fifteenth condition or a sixteenth condition,
in the ninth condition, a second opposing mass of the second opposing beam electrode is different from the first opposing mass of the first opposing beam electrode,
in the tenth condition, at least a part of a second opposing material included in the second opposing beam electrode is different from at least a part of a first opposing material included in the first opposing beam electrode,
in the eleventh condition, a second opposing thickness along the third direction of the second opposing beam electrode is different from a first opposing thickness along the third direction of the first opposing beam electrode,
in the twelfth condition, a second opposing size of a second opposing hole included in the second opposing beam electrode is different from a first opposing size of a first opposing hole included in the first opposing beam electrode,
in the thirteenth condition, a second opposing density of the second opposing holes is different from a first opposing density of the first opposing holes,
in the fourteenth condition, a second opposing number of the second opposing holes is different from a first opposing number of the first opposing holes, or the second opposing beam electrode includes the second opposing hole and the first opposing beam electrode does not include the first opposing hole,
in the fifteenth condition, a second opposing layer structure of the second opposing beam electrode is different from a first opposing layer structure of the first opposing beam electrode, and
in the sixteenth condition, a second opposing shape of the second opposing beam electrode is different from a first opposing shape of the first opposing beam electrode.

11. The sensor according to claim 2, wherein
a position of the first other portion in the first direction is provided between a position of the first portion in the first direction and a position of the second portion in the first direction, and
a position of the second other portion in the first direction is provided between the position of the first other portion in the first direction and the position of the second portion in the second direction.

12. The sensor according to claim 11, wherein
the element section further includes a movable member supported by the first fixed portion,
the movable member includes a first movable portion,
the first other portion and the second other portion are connected to the first movable portion,
the first support portion includes a first support region, a second support region, and a third support region,
the first portion is supported by the first support region, the second portion is supported by the second support region, and
the first movable part is supported by the third support region.

13. The sensor according to claim 12, wherein
the movable member further includes
a first movable base portion supported by the third support region, and
a first movable connecting portion provided between the first movable base portion and the first movable portion,
a first movable connecting portion width of the first movable connecting portion in the first direction is narrower than a first movable base width of the first movable base in the first direction, and
a first movable connecting portion width is narrower than a first movable portion width of the first movable portion in the first direction.

14. The sensor according to claim 13, wherein
the movable member further includes a first movable weight portion connected to the first movable portion,
the first movable portion is provided between the first movable connecting portion and the first movable weight portion in the second direction, and
a first movable weight portion width in the first direction of the first movable weight portion is wider than the first movable portion width.

15. The sensor according to claim 11, wherein
the first beam electrode includes
a first extending portion extending along the first direction, and
a first extending connecting portion connecting the first extending portion to the first intermediate portion,
the second beam electrode includes
a second extending portion extending along the second direction, and
a second extending connecting portion connecting the second extending portion to the second intermediate portion.

16. The sensor according to claim 15, wherein
the first beam electrode includes a plurality of the first extending portions,
one of the plurality of first extending portions is provided between the first beam and another one of the plurality of first extending portions,
a length of the plurality of first extending portions along the first direction is longer than a length of the other one of the plurality of first extending portions along the first direction,
the second beam electrode includes a plurality of the second extending portions,
one of the plurality of second extending portions is provided between the second beam and another one of the plurality of second extending portions, and
a length of the one of the plurality of second extending portions along the first direction is longer than a length of the other one of the plurality of second extending portions along the first direction.

17. The sensor according to claim 11, wherein
the element section includes
a first opposing beam electrode connected to the first intermediate portion, and
a second opposing beam electrode connected to the second intermediate portion,
the first beam is provided between the first opposing beam electrode and the first beam electrode in the second direction, and
the second beam is provided between the second opposing beam electrode and the second beam electrode in the second direction.

18. The sensor according to claim 11, wherein
the element section includes
a first opposing beam including a first opposing portion, a first other opposing portion, and a first opposing intermediate portion between the first opposing portion and the first other opposing portion, a direction from the first opposing portion to the first other opposing portion being along the first direction,
a first opposing beam electrode connected to the first opposing intermediate portion,
a second opposing beam including a second opposing portion, a second other opposing portion, and a second opposing intermediate portion between the second opposing portion and the second other opposing portion, a direction from the second opposing portion to the second other opposing portion being along the first direction, and
a second opposing beam electrode connected to the second opposing intermediate portion.

19. The sensor according to claim 2, further comprising:
a controller; and
a first fixed electrode and a second fixed electrode fixed to the base,
the first fixed electrode facing the first beam electrode,
the second fixed electrode facing the second beam electrode,
the controller being configured to apply a first AC signal between the first fixed electrode and the first beam electrode, and
the controller being configured to apply the first AC signal between the second fixed electrode and the second beam electrode.

20. An electronic device, comprising:
the sensor according to claim 1; and
a circuit controller configured to control a circuit based on a signal obtained from the sensor.
